(19) United States
(12) Patent Application Publication
(10) Pub. No.: US 2017/0169075 A1
(43) Pub. Date: Jun. 15, 2017

(54) TESTING APPARATUSES, HIERARCHICAL PRIORITY ENCODERS, METHODS FOR CONTROLLING A TESTING APPARATUS, AND METHODS FOR CONTROLLING A HIERARCHICAL PRIORITY ENCODER

(71) Applicant: Agency for Science, Technology and Research, Singapore (SG)

(72) Inventors: Wenyu JIANG, Singapore (SG); Rongshan YU, Singapore (SG); Xiaoming BAO, Singapore (SG); Susanto RAHARDJA, Singapore (SG)

(73) Assignee: Agency for Science, Technology and Research, Singapore (SG)

(21) Appl. No.: 15/121,991

(22) PCT Filed: Mar. 2, 2015
(86) PCT No.: PCT/SG2015/000065

§ 371 Date: Aug. 26, 2016

(30) Foreign Application Priority Data
Feb. 28, 2014 (SG) 10201400292T
Feb. 28, 2014 (SG) 10201400303Y

(51) Int. Cl. G06F 17/30; G11C 16/26; G11C 16/04; G06F 3/06

(52) U.S. Cl. CPC G06F 17/30519; G06F 3/061; G06F 3/0629; G06F 3/0679; G11C 16/26; G11C 16/0483

(57) ABSTRACT

According to various embodiments, a testing apparatus may be provided. The testing apparatus may include: a cell pair comprising two l-bit memory cells configured to represent a stored pattern of l-bit; and a converter configured to convert a query pattern of l-bit into a pair of voltages defined such that when applied to gates of the cell pair, the voltages make the cell pair into high resistance mode when the query pattern matches the stored pattern and into low resistance mode when the query pattern does not match the stored pattern.

### CROSS-REFERENCE TO RELATED APPLICATIONS

The present application claims the benefit of the Singapore patent application No. 10201400292T filed on 28 Feb. 2014, the entire contents of which are incorporated herein by reference for all purposes. The present application furthermore claims the benefit of the Singapore patent application No. 10201400303Y filed on 28 Feb. 2014, the entire contents of which are incorporated herein by reference for all purposes.

### TECHNICAL FIELD

Embodiments relate generally to testing apparatuses, hierarchical priority encoders, methods for controlling a testing apparatus, and methods for controlling a hierarchical priority encoder.

### BACKGROUND

Finding the most similar matches to a query vector from a large database of vectors, also known as Nearest Neighbor (NN) search, is a well-known problem in audio, video and other information retrieval, particularly audio/video fingerprinting, which tries to identify a query audio/video clip from a database of reference audio/video content. Exact NN search is challenging when the vectors have high dimensions, where no indexing structure is known to be consistently faster than brute-force search. For approximate NN (ANN), commonly used methods such as Locality Sensitive Hashing (LSH) either become slow due to excessive number of hard disk seeks, or have to use an excessive amount of main memory for indexing, when the NN distance to query vector is far and the database is large. Thus, there may be a need for more efficient methods and devices.

### SUMMARY

According to various embodiments, a testing apparatus may be provided. The testing apparatus may include: a cell pair comprising two l-bit (or more generally k-state) memory cells configured to represent a stored pattern of l-bit (or more generally k-state); and a converter configured to convert a query pattern of l-bit (or more generally k-state) into at least a pair of voltages defined such that when applied to gates of the cell pair, the voltages make the cell pair into either a high resistance mode or a low resistance mode, depending on whether the query pattern matches the stored pattern. In one embodiment, the voltages make the cell pair into high resistance mode when the query pattern matches the stored pattern and into low resistance mode when the query pattern does not match the stored pattern. In another embodiment, where the cell is made of a transistor serially connected to a programmable resistive element (i.e. NGMEM such as RRAM, PCRAM, or MRAM), the voltages make the cell pair into low resistance mode when the query pattern matches the stored pattern and into high resistance mode when the query pattern does not match the stored pattern.

According to various embodiments, a hierarchical priority encoder may be provided. The hierarchical priority encoder may include a multi-match controller configured to report multiple matches in case of multiple matches.

According to various embodiments, a method for controlling a testing apparatus may be provided. The method may include: controlling a cell pair of the testing apparatus, the cell pair comprising two l-bit (or more generally k-state) memory cells configured to represent a stored pattern of l-bit (or more generally k-state); and converting a query pattern of l-bit (or more generally k-state) into a pair of voltages defined such that when applied to gates of the cell pair, the voltages make the cell pair into either a high resistance mode or a low resistance mode, depending on whether the query pattern matches the stored pattern. In one embodiment, the voltages make the cell pair into high resistance mode when the query pattern matches the stored pattern and into low resistance mode when the query pattern does not match the stored pattern. In another embodiment, where the cell is made of a transistor serially connected to a programmable resistive element, the voltages make the cell pair into low resistance mode when the query pattern matches the stored pattern and into high resistance mode when the query pattern does not match the stored pattern.

According to various embodiments, a method for controlling a hierarchical priority encoder may be provided. The method may include controlling a multi-match controller of the hierarchical priority encoder to report multiple matches in case of multiple matches.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A shows a testing apparatus according to various embodiments;

FIG. 1B shows a server according to various embodiments;

FIG. 1C shows a flow diagram illustrating a testing method according to various embodiments;

FIG. 1D shows a testing apparatus 130 according to various embodiments;

FIG. 1E shows a hierarchical priority encoder 138 according to various embodiments;

FIG. 1F shows a flow diagram 142 illustrating a method for controlling a testing apparatus;

FIG. 1G shows a flow diagram 148 illustrating a method for controlling a hierarchical priority encoder;

FIG. 2 shows an illustration of an interlocked design;

FIG. 3 shows an illustration 300 of an interlocked design according to various embodiments compatible with 1T1R (1-transistor 1-resistor) version of RRAM, PCRAM or even MRAM;

FIG. 4 shows an illustration of an extended interlocked design according to various embodiments;

FIG. 5 shows an illustration of a 2-Transistor Flash cell based on standard logic CMOS process;

FIG. 6 shows an illustration of a 2-cell NAND string based on individual cell in FIG. 5;

FIG. 7A and FIG. 7B show NAND Flash based on standard logic CMOS process;

FIG. 8 shows an illustration of one layout method for example Flash cell array;

FIG. 9 shows an illustration of another layout for example Flash array;

FIG. 10A and FIG. 10B show an example 2×2 NOR Flash cell array;

FIG. 11A and FIG. 11B show an adaption of 2TS NOR Flash cells;

FIG. 12 and FIG. 13 illustrate a method according to various embodiments for reducing program disturbs;

FIG. 14 and FIG. 15 show example operating conditions of SS-CHE split-gate NOR Flash cells;

FIG. 16 and FIG. 17 illustrate a shielded bit-line sensing method;

FIG. 18A, FIG. 18B, FIG. 18C, FIG. 18D and FIG. 18E illustrate adapting the 1-bit NAND-Flash based interlocked design to NOR Flash;

FIG. 19 shows an illustration of an adaption of 1-bit interlocked design to next-generation memory;

FIG. 20 shows an illustration of types of range queries in an l-bit fGT MLC pair and their semantic meanings;

FIG. 21A and FIG. 21B illustrate a circuit for implementing interlocked design on NOR Flash;

FIG. 22A and FIG. 22B illustrate a comparison of row-wise and column-wise cell programming method;

FIG. 23A, FIG. 23B, and FIG. 23C illustrate implementing row-wise vs. column-wise erase operation for SuperFlash v1-2;

FIG. 24A and FIG. 24B illustrate example ways of merging source diffusions in the same column to form a Source line;

FIG. 25A and FIG. 25B illustrate hierarchical merging of tie-breaking and feedback of which column to clear after it is reported;

FIG. 26A, FIG. 26B, FIG. 26C, FIG. 26D, and FIG. 26E illustrate an hierarchical implementation of candidate column ID reporting and auto-clearing of candidate after being reported;

FIG. 27 shows an illustration of a hierarchical merging of sub-array priority encoders into a large-scale priority encoder;

FIG. 28 shows an illustration of a block diagram of a shared priority encoder (and shared vote counters) among multiple sub-arrays according to various embodiments;

FIG. 29 shows an illustration-of a scalable inter-chip design according to various embodiments; and

FIG. 30 shows an illustration of an example timing sequence of the complete query output process according to various embodiments.

### DESCRIPTION

Embodiments described below in context of the devices are analogously valid for the respective methods, and vice versa. Furthermore, it will be understood that the embodiments described below may be combined, for example, a part of one embodiment may be combined with a part of another embodiment.

In this context, the testing apparatus as described in this description may include a memory which is for example used in the processing carried out in the testing apparatus. In this context, the server as described in this description may include a memory which is for example used in the processing carried out in the server. A memory used in the embodiments may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory).

In an embodiment, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail below may also be understood as a “circuit” in accordance with an alternative embodiment.

Previously, a low-power hardware design called the interlocked design was provided to transform NAND Flash memory into a high-performance, low-power multimedia search engine. In its simplest form, it may use 2 NAND Flash cells to represent 1 bit, with a unique pair of probing voltages for testing == =“0” (in other words, for testing whether a query information is identical to “0”), and another unique pair of probing voltages for testing == “1” (in other words, for testing whether a query information is identical to “1”). The cell pair conducts if and only if probing voltage pair matches the represented bit. By concatenating m such cell pairs in a NAND string (a NAND string is a complete serial circuit of NAND Flash cells), an m-bit == test operation can be implemented, by in unique pairs of probing voltages applied to the WordLines (WLs) of the NAND string. Then, a probed NAND string will conduct or draw non-negligible current if and only if its stored data matches the entire m-bit query input. Such an m-bit (or more generally, in-component) query or reference pattern may be referred to herein as a sub-pattern.

Finding the most similar matches to a query vector from a large database of vectors, also known as Nearest Neighbor (NN) search, is a well-known problem in audio, video and other information retrieval, particularly audio/video fingerprinting, which tries to identify a query audio/video clip from a database of reference audio/video content. Exact NN search is challenging when the vectors have high dimensions, where no indexing structure is known to be consistently faster than brute-force search. For approximate NN (ANN), commonly used methods such as Locality Sensitive Hashing (LSH) either become slow due to excessive number of hard disk seeks, or have to use an excessive amount of main memory for indexing, when the NN distance to query vector is far and the database is large. According to various embodiments, efficient methods and devices for finding most similar matched may be provided.

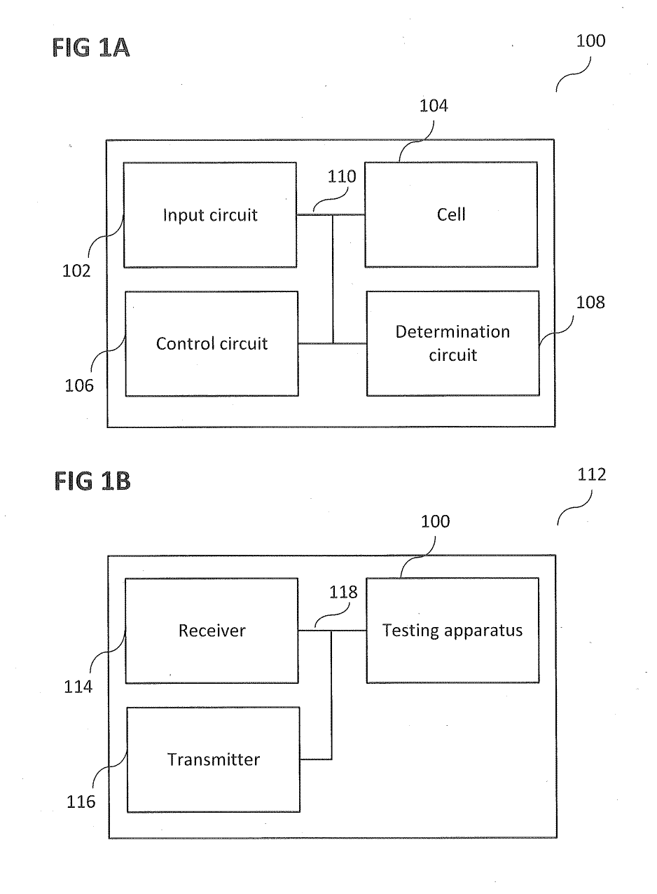

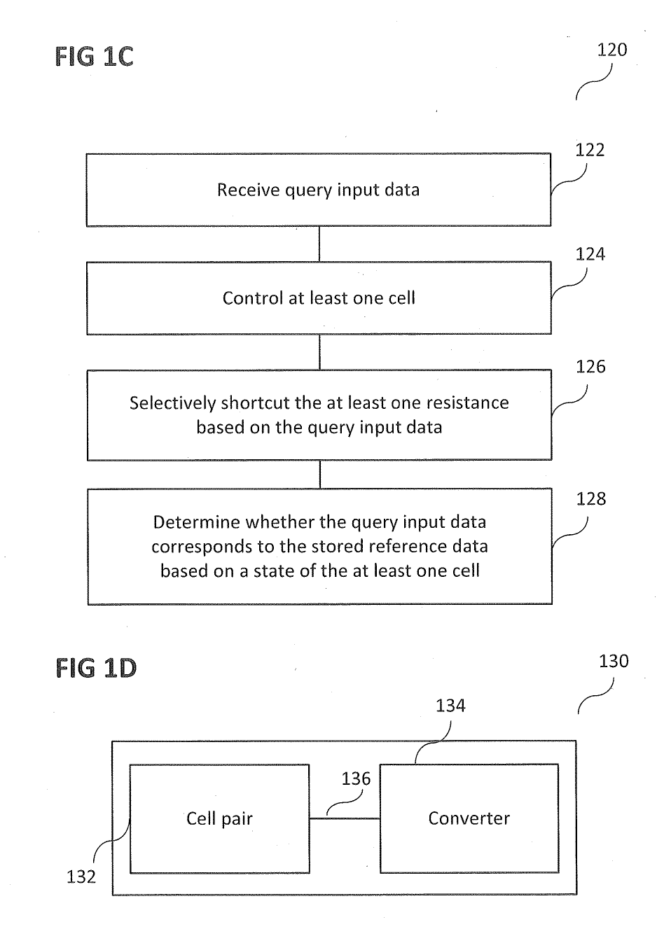

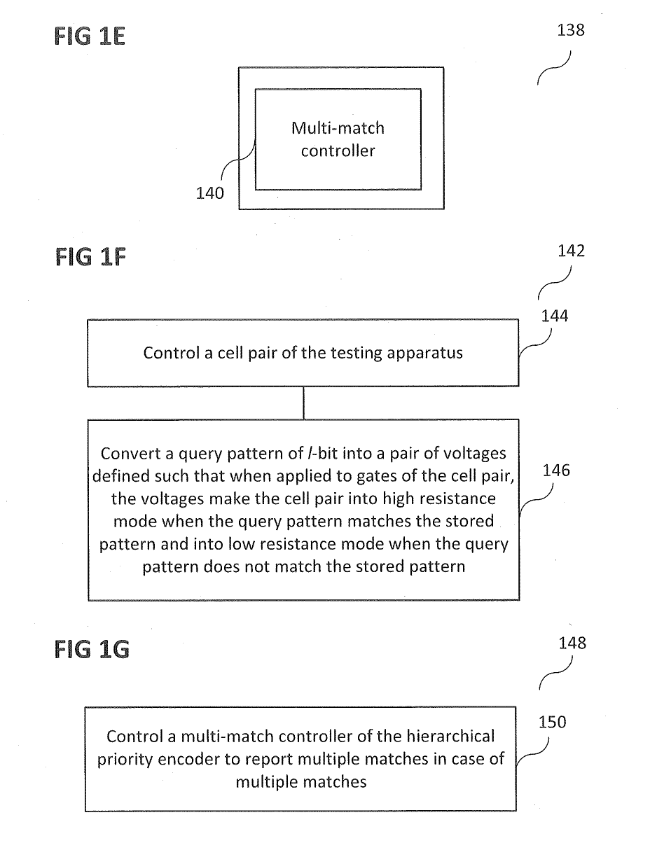

FIG. 1A shows a testing apparatus 100 according to various embodiments. The testing apparatus 100 may include an input circuit 102 configured to receive query input data. The testing apparatus 100 may further include at least one cell 104. The at least one cell 104 may include a memory circuit configured to store reference data. The cell 104 may further include at least one resistance coupled to the memory circuit. In case of a plurality of cells, each cell may include a respective memory circuit, which together may store the reference data, and each one of the respective memory circuits may be coupled with a respective resistance. The testing apparatus 100 may further include a control circuit 106 configured to selectively shortcut the at least one resistance based on the query input data. The testing apparatus 100 may further include a determination circuit 108 configured to determine whether the query input data corresponds to the stored reference data based on a state of the at least one cell 104. The input circuit 102, the at least one cell 104, the control circuit 106, and the determination circuit 108 may be coupled with each other, like indicated by lines 110, for example electrically coupled, for example using a line or a cable, and/or mechanically coupled.

According to various embodiments, the at least one cell 104 may include a plurality of transistors, each of the transistors connected to a corresponding resistance. According to various embodiments, the control circuit 106 may be configured to selectively shortcut at least one of the resistances to which the plurality of transistors correspond based on the query input data.

According to various embodiments, the at least one cell 104 may include a first transistor connected to a first resistance. According to various embodiments, the at least one cell 104 may include a second transistor connected to a second resistance. According to various embodiments, the control circuit 106 may be configured to selectively shortcut the first resistance or the second resistance based on the query input data.

According to various embodiments, a “0” may be stored as a (H L) pair in the first transistor and the second transistor, where L denotes low-resistance state, and H denotes high-resistance state.

According to various embodiments, a “1” may be stored as a (L H) pair in the first transistor and the second transistor, where L denotes low-resistance state, and H denotes high-resistance state.

According to various embodiments, the first resistor may be connected with a first MOSFET in parallel. According to various embodiments, the second resistor may be connected with a second MOSFET in parallel.

According to various embodiments, the first MOSFET is a first nMOSFET. According to various embodiments, the second MOSFET is a second nMOSFET. According to various embodiments, for query input data equal to “0”, a hi voltage may be applied to the first nMOSFET, and a lo voltage may be applied to the second nMOSFET. According to various embodiments, hi may be a voltage high enough to make the first nMOSFET turn ON, and lo may be a voltage low enough to make the second nMOSFET turn OFF;

According to various embodiments, the first MOSFET may be a first nMOSFET. According to various embodiments, the second MOSFET may be a second nMOSFET. According to various embodiments, for query input data equal to “1”, a lo voltage may be applied to the first nMOSFET, and a hi voltage may be applied to the second nMOSFET. According to various embodiments, hi may be a voltage high enough to make the second nMOSFET turn ON, and lo may be a voltage low enough to make the first nMOSFET turn OFF.

According to various embodiments, the memory circuit may include at least one circuit selected from a list of circuits consisting of: of a NAND flash architecture; a NOR flash architecture; a 2-transistor source-select NOR flash cell; a Ss-CHE split-gate NOR flash cell; and a SuperFlash v1-2 or v3 NOR type cell.

FIG. 1B shows a server 112 according to various embodiments. The server 112 may include a receiver 114 configured to receive a query input data from a client. The server 112 may further include a testing apparatus (for example the testing apparatus 100 like shown in FIG. 1A). The server 112 may further include a transmitter 116 configured to transmit a result determined by the determination circuit of the testing apparatus 100 to the client. The receiver 114, the testing apparatus 100, and the transmitter 116 may be coupled with each other, like indicated by lines 118, for example electrically coupled, for example using a line or a cable, and/or mechanically coupled.

According to various embodiments, the server 112 may further include a hierarchical priority encoder (not shown in FIG. 1B) configured to report a match based on the determination of the determination circuit.

FIG. 1C shows a flow diagram 120 illustrating a testing method according to various embodiments. In 122, query input data may be received. In 124, at least one cell may be controlled, the cell including a memory circuit configured to store reference data, the cell further including at least one resistance coupled to the memory circuit. In 126, the at least one resistance may be selectively shortcutted based on the query input data. In 128, it may be determined whether the query input data corresponds to the stored reference data based on a state of the at least one cell.

According to various embodiments, the at least one cell may include a plurality of transistors, each of the transistors connected to a corresponding resistance. According to various embodiments, the testing method may further include selectively shortcutting at least one of the resistances to which the plurality of transistors correspond based on the query input data.

According to various embodiments, the at least one cell may include a first transistor connected to a first resistance. According to various embodiments, the at least one cell may further include a second transistor connected to a second resistance. According to various embodiments, the testing method may further include selectively shortcutting the first resistance or the second resistance based on the query input data.

According to various embodiments, a “0” may be stored as a (H L) pair in the first transistor and the second transistor, where L denotes low-resistance state, and H denotes high-resistance state.

According to various embodiments, a “1” may be stored as a (L H) pair in the first transistor and the second transistor, where L denotes low-resistance state, and H denotes high-resistance state.

According to various embodiments, the first resistor may be connected with a first MOSFET in parallel. According to various embodiments, the second resistor may be connected with a second MOSFET in parallel.

According to various embodiments, the first MOSFET may be a first nMOSFET. According to various embodiments, the second MOSFET may be a second nMOSFET. According to various embodiments, for query input data equal to “0”, a hi voltage may be applied to the first nMOSFET, and a lo voltage may be applied to the second nMOSFET. According to various embodiments, hi may be a voltage high enough to make the first nMOSFET turn ON, and lo may be a voltage low enough to make the second nMOSFET turn OFF;

According to various embodiments, the first MOSFET may be a first nMOSFET. According to various embodiments, the second MOSFET may be a second nMOSFET. According to various embodiments, for query input data equal to “1”, a lo voltage may be applied to the first nMOSFET, and a hi voltage may be applied to the second nMOSFET. According to various embodiments, hi may be a voltage high enough to make the second nMOSFET turn ON, and lo may be a voltage low enough to make the first nMOSFET turn OFF;

According to various embodiments, the memory circuit may include at least one circuit selected from a list of circuits consisting of: of a NAND flash architecture; a NOR flash architecture; a 2-transistor source-select NOR flash cell; a Ss-CHE split-gate NOR flash cell; and a SuperFlash v1-2 NOR type cell.

FIG. 1D shows a testing apparatus 130 according to various embodiments. The testing apparatus 130 may include a cell pair 132. The cell pair 132 may include or may be two l-bit (or more generally k-state) memory cells configured to represent a stored pattern of l-bit (or more generally k-state). The testing apparatus 130 may further include a converter 134 configured to convert a query pattern of l-bit (or more generally k-state) into a pair of voltages defined such that when applied to gates of the cell pair 132, the voltages make the cell pair 132 into either a high resistance mode or a low resistance mode, depending on whether the query pattern matches the stored pattern. In one embodiment, the voltages make the cell pair 132 into high resistance mode when the query pattern matches the stored pattern, and into low resistance mode when the query pattern does not match the stored pattern. The cell pair 132 and the converter may be coupled with each other, like indicated by lines 136, for example electrically coupled, for example using a line or a cable, and/or mechanically coupled. It will be understood that “l-bit” may be understood as “having a length of l bits”, and that “k-state” may be understood as “able to take on one out of k unique states”, and that a “k-state value” may be understood as “a numerical value assigned to denote one of such k unique states”. In another embodiment, where the cell is made of a transistor serially connected to a programmable resistive element, the voltages make the cell pair into low resistance mode when the query pattern matches the stored pattern and into high resistance mode when the query pattern does not match the stored pattern.

According to various embodiments, l may be equal to 1. According to various embodiments, the cell pair 132 may include at least one of 1-Tr NOR Flash, 2TS NOR Flash default, 2TS NOR Flash with mid-only voltage to word lines, SuperFlash v1-2, SuperFlash v3, or NGMEM (e.g. RRAM, PCRAM, or MRAM).

According to various embodiments, l may be an integer number larger than 1. According to various embodiments, the cell pair 132 may include at least one of 1-Tr NOR Flash, 2TS NOR Flash default, SuperFlash v1-2, SuperFlash v3, or NGMEM.

FIG. 1E shows a hierarchical priority encoder 138 according to various embodiments. The hierarchical priority encoder 138 may include a multi-match controller 140 configured to report multiple matches in case of multiple matches.

According to various embodiments, the hierarchical priority encoder 138 may further include a merging circuit (not shown in FIG. 1E) configured to provide hierarchical merging (e.g. with the merging formulas for PE decision and PE column ID like described herein).

According to various embodiments, the multi-match controller 140 may be configured to report multiple matches by clearing a previously reported match after each report.

According to various embodiments, the multi-match controller 140 may be configured to provide a hierarchically back-traverse mechanism.

According to various embodiments, the multi-match controller 140 may be configured to provide a general column-ID to N decoder.

According to various embodiments, the hierarchical priority encoder 138 may be configured for multi-array operation.

According to various embodiments, the hierarchical priority encoder 138 may be configured for multi-chip operation.

FIG. 1F shows a flow diagram 142 illustrating a method for controlling a testing apparatus. In 144, a cell pair of the testing apparatus may be controlled. The cell pair may include or may be two l-bit memory cells configured to represent a stored pattern of l-bit. In 146, a query pattern of l-bit may be converted into a pair of voltages defined such that when applied to gates of the cell pair, the voltages make the cell pair into high resistance mode when the query pattern matches the stored pattern and into low resistance mode when the query pattern does not match the stored pattern.

According to various embodiments, l may be equal to 1. According to various embodiments, the cell pair may include or may be at least one of 1-Tr NOR Flash, 2TS NOR Flash default, 2TS NOR Flash with mid-only voltage to word lines, SuperFlash v1-2, SuperFlash v3, or NGMEM.

According to various embodiments, wherein l may be an integer number larger than 1. According to various embodiments, the cell pair may include or may be at least one of 1-Tr NOR Flash, 2TS NOR Flash default, SuperFlash v1-2, SuperFlash v3, or NGMEM.

FIG. 1G shows a flow diagram 148 illustrating a method for controlling a hierarchical priority encoder. In 150, a multi-match controller of the hierarchical priority encoder may be, controlled to report multiple matches in case of multiple matches.

According to various embodiments, the method may further include controlling a merging circuit to provide hierarchical merging.

According to various embodiments, the multi-match controller may report multiple matches by clearing a previously reported match after each report.

According to various embodiments, the multi-match controller may provide a hierarchically back-traverse mechanism.

According to various embodiments, the multi-match controller may provide a general column-ID to N decoder.

According to various embodiments, the hierarchical priority encoder may provide multi-array operation.

According to various embodiments, the hierarchical priority encoder may provide multi-chip operation.

According to various embodiments, a low-power design using Vₚᵣₑ (instead of Ground) level shielded Bit-line sensing for NAND Flash may be provided.

According to various embodiments, an interlocked design for NAND architecture of NGMEM may be provided.

According to various embodiments, a way of converting 2TS NOR Flash to NAND Flash while not requiring process re-engineering may be provided.

According to various embodiments, scalable Fuzzy search systems may be provided.

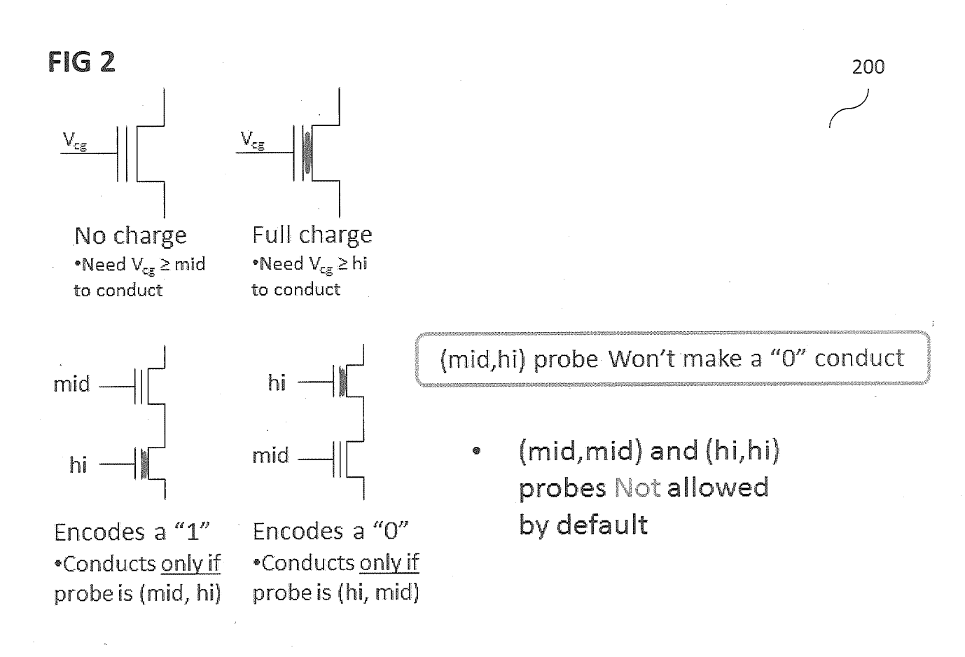

FIG. 2 shows an illustration 200 of the interlocked design for the above-mentioned 1-bit quantization case. In other words, FIG. 2 shows an illustration 200 of the interlocked design for 1-bit == test case.

NAND Flash cells are floating gate transistors, which has the notion of threshold voltage Vₜₕ (for example as viewed from its Control Gate). If the, applied voltage to the cell's Control Gate (i.e., WL) V_{CG} is below Vₜₕ, the cell does not conduct, i.e., draws very little current. The cell's current grows (at least substantially; in other words: roughly) exponentially with respect to V_{CG}, until V_{CG} becomes much larger than Vₜₕ. By contrast, many of the next-generation memories (NGMEM) such as RRAM (Resistive RAM), PCRAM (Phase-Change RAM), MRAM (Magnetic RAM), are inherently resistive devices with programmable resistance, as opposed to a transistor with programmable threshold voltage. Although a transistor is often used together with the resistive element in such memories, the transistor serves only as a selector switch and generally has no programmable Vₜₕ. Therefore, even if a relatively low input voltage is applied, generally to the bit-line (BL) instead of the WL, a non-negligible current generally may still flow through the resistive element even if it is in a high resistance state (unless the high resistance is very high).

In conventional RRAM, PCRAM, or even MRAM, within each column their cells follow a parallel layout similar to DRAM or NOR Flash. Now if their cells are instead concatenated to follow a NAND/serial layout, this serial circuit may also be called a NAND string, then we are measuring the sum of resistance across all cells in such a NAND string. Suppose a low resistance state L has resistance R_{L}, and high resistance state H has resistance R_{H}.

If we want to use the interlocked low-power design, for example by using a (H, L) cell state pair to represent a “0”, and using a (L,H) cell state pair to represent a “1”, then we have difficulty distinguishing between a “0” and “1” if we only observe the BL (bit-line) current (or its corresponding BL voltage). This is because the 2 select transistors in the cell pair both need to be ON to test each cell's resistance state, and yet the total resistance is the same for both represented “0” and “1”: R_{L}+R_{H} (assuming select transistors have equivalent resistance <<R_{L} in the ON state).

According to various embodiments, an interlocked design may be provided, for example for next-generation memories.

In the following, a baseline case of one cell pair according to various embodiments will be described.

To resolve the above-mentioned ambiguity, we can selectively “by-pass” one of the two resistive elements in the cell pair. We can add a “by-pass” transistor in parallel connection to the resistive element in the cell. So for each cell pair there will be 2 “by-pass” transistors. It is to be noted that, to save input pins, we can borrow from the concept of interlocked design, and use 1 nMOSFET and 1 pMOSFET as the 2 “by-pass” transistors and with a common control voltage input referred to as Probe or Query.

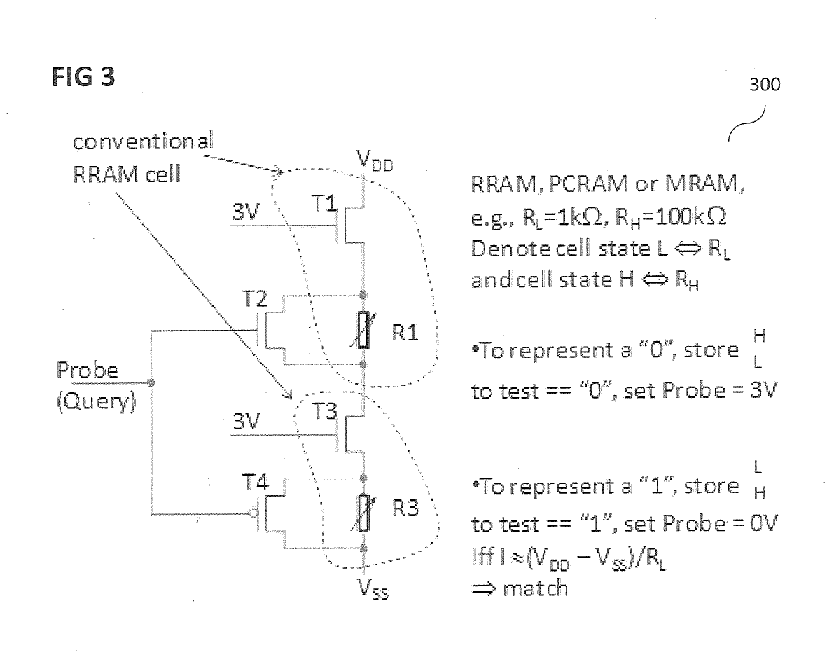

This is illustrated in FIG. 3.

FIG. 3 shows an illustration 300 of an interlocked design according to various embodiments compatible with 1T1R (1-transistor 1-resistor) version of RRAM, PCRAM or even MRAM. T1's corresponding resistive element R1 is drawn beneath T1, although R1 may also be above T1, though this doesn't really affect the design here.

To test for == “0”, Probe=3V (high voltage) is used. It will turn on T2 and by-pass top cell's resistive element R1, Yet 3V will turn off the pMOSFET T4 (assume V_{DD}≦3V), so only bottom cell's resistive element. R3 will be measured. Assuming the select and by-pass transistors have much lower resistance than R_{L}, if == “0” is true, then we get NAND string BL current I≈(V_{DD}−V_{SS})/R_{L}. If == “0” is false, I≈(V_{DD}−V_{SS})/R_{H}. For RRAM, which can have a fairly high 100:1 resistance ratio or above, this will result in a 100:1 current ratio or above, which may be easy to distinguish. Plus, the non-matching cell pair will draw much less current, similar to NAND Flash interlocked design where non-matching cell pair draws almost zero current: The design in FIG. 3 is also applicable to PCRAM and MRAM, or any programmable resistive memory device, as long as the resistance ratio is sufficiently high, and/or the noise in measured current ratio (caused by variability in programmed resistance and/or circuit measurement noise) is sufficiently small, so that the currents between == and != are sufficiently distinguishable.

To test for == “1”, Probe =0V (low voltage) is used. It will turn off T2, but will turn on T4 and bypass R3. Therefore, the top cell's resistive element R1 will be measured. If == “1” is true, I≈(V_{DD}−V_{SS})/R_{L}. If == “1” is false, I≈(V_{DD}−V_{SS})/R_{H}. Therefore, for both == “0” and == “1” tests, a match corresponds to a large current and no-match corresponds to a small current.

In the following, advanced uses according to various embodiments, for example multi-bit == tests and transistor count minimization, will be described.

Multiple cell pairs may be concatenated in series to support == test for multiple bits. If all n bits in a pattern match and the NAND string is n pairs long, then BL current I≈(V_{DD}−V_{SS})/(n*R_{L}); otherwise, I≧(V_{DD}−V_{SS})/(R_{H}+(n−1)*R_{L}). If cells haves 100:1 resistance ratio, then current differentiation will still be fairly good for n=32.

It is to be note that T2 and T4 in FIG. 3 are similar to a CMOS-based (wherein CMOS may stand for Complementary metal-oxide-semiconductor) inverter. Such an inverter has the pMOSFET closer to V_{DD} for more stable operation, and we can move T4, T3, R3 together to the top to be closer to V_{DD} as well, but when concatenating multiple cell pairs, the lower pairs' pMOSFET will still not be close to V_{DD} no matter how we arrange the pMOSFETs.

Furthermore, because T1 and T3 are always fed with 3V (high voltage), they can actually be omitted without causing any trouble. If there are multiple NAND strings per column/BL (often the case), then we only need a T1 (one select transistor) per NAND string to prevent unwanted current from unprobed NAND strings.

In the following, extensions according to various embodiments to the interlocked design will be described, for example illustrating how to allow data initialization and modification.

The new interlocked design in FIG. 3 can be concatenated in cell pairs to form a long NAND string, and this works as long as the data in these cells have been properly initialized. However, the working mechanisms of MRAM, PCRAM and RRAM all require applying some voltage or current to alter the cell state. So if multiple cells are in series, the applied voltage or current will generally affect all of these cells, instead of the one intended to be programmed or altered.

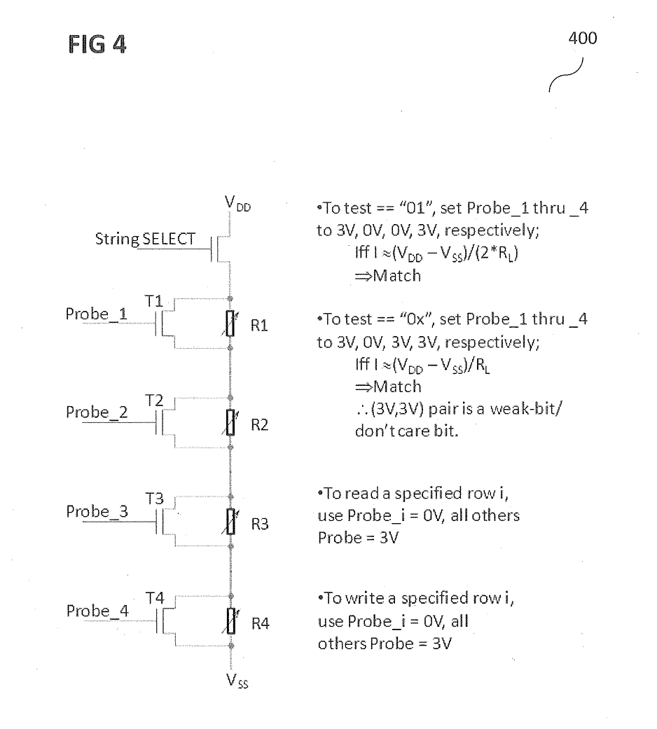

FIG. 4 shows an illustration 400 of an extended interlocked design according to various embodiments after omitting unnecessary select transistors and making interlocked probe input pair independent.

For example like shown in FIG. 4, FIG. 3 may be extended by changing T4 from a pMOSFET to an nMOSFET, and T2 and T4 each will have independent input line. During search/query mode, T2 and T4 will be in interlocked voltages, that is, to test for == “0”, Probe to T2 and T4 will be 3V and 0V, respectively; and to test for == “1”, Probe to T2 and T4 will be 0V and 3V, respectively. Whereas during data writing, all by-pass transistors will have 3V (high voltage) so that their corresponding resistive elements are not (significantly) affected. Only the bypass transistor whose corresponding resistive element is to be programmed or altered will have 0V (low voltage). Assuming the combined resistance of all bypass transistors is still relatively small, such modification will work.

FIG. 4 illustrates how this can be done. Since select transistors like T1 and T3 in FIG. 3 may be omitted, in FIG. 4 each transistor and resistive element are renamed to make it easier to read. It is to be noted that the Probe_i inputs are now essentially like WordLines in terms of functionality. For example, to test for == “01” in FIG. 4, Probe_1 thru Probe_4 should be 3V, 0V, 0V, 3V, respectively, with I≈(V_{DD}−V_{SS})/(2*R_{L}) if pattern matches.

In the following, weak-bit representation according to various embodiments will be described.

For media fingerprinting or other applications of nearest neighborhood search, the concept of “weak-bits” has been introduced to represent bits that are most likely to have flipped from original to query within a codeword. Typically, to improve the robustness of the search algorithm those “weak-bits” are ignored during matching operation. “Weak-bits” can be identified by fingerprinting generation algorithm during database generation (database- or reference-side weak bits) or during query generation (query side weak bits). Pattern matching with weak-bits is supported natively in the NAND Flash interlocked design, with the advantage that no enumeration of weak bits (2^{w} enumerations for w weak bits) is needed, and the pattern match can be done in just one NAND Flash access cycle.

Weak-bits can be implemented using the interlock design illustrated in FIG. 4. To represent a database side weak-bit, store (L, L) to both interlocked transistors (e.g., T1 and T2) so that a match will be generated regardless of the probe voltages. To represent a query side weak-bit, probe both interlocked transistors with high voltage (3V) so that both by-pass transistors are conducted and a match will be generated regardless of the memory status. Such representation has the same advantage that no weak-bit enumeration is required, and the pattern match can be done in just one memory access cycle (though this cycle may be somewhat longer than the conventional memory access cycle because the serial circuit of a NAND string will introduce more delay than the parallel circuit in conventional RRAM, PCRAM and MRAM, etc.).

Therefore, to test for == “0x” in FIG. 4, Probe_1 thru Probe_4 should be 3V, 0V, 3V, 3V, respectively, with I≈(V_{DD}−V_{SS})/R_{L} if pattern matches. Reference-side weak-bit can be designed as a (L,L) cell state pair, although this will result in a resistance of up to 2*R_{L} if probe pair is (0V,0V), whereas the resistance will be R_{L} if probe pair is (3V,0V) or (0V,3V), and the resistance will be very small if probe pair is (3V,3V), assuming by-pass transistors have much lower resistance than the resistive elements. Therefore careful current estimations need to be done to come up with appropriate current threshold(s) for checking whether the pattern is matching.

The resistive elements may support MLC (multi-level cell) by different levels of resistance. This may be used to provide fuzzy pattern matching, although the exact functionality may be different from weak ranges or range quantizers in NAND Flash based interlocked design.

In the following, generalizations for other embodiments will be described.

It is to be noted that. FIG. 3 and FIG. 4 are illustrative embodiments only, and various other embodiments and generalizations may be made from them. For example, we may assume T1 thru T4 all have the same threshold voltage Vₜₕ which is substantially smaller than 3V but also substantially larger than 0V. In practice, T1 and T2 may have different Vₜₕ, and the input voltage to T1 and T2 can also be adjusted accordingly, so that T1 should be ON, while. T2 should be ON if == “0” test is to be performed. Also, the representation in FIG. 3, where a top-bottom pair of (H L) represents a “0” and (L H) represents a “1”, can be swapped to create an alternative/dual representation. Similarly, due to the duality of nMOSFETs and pMOSFETs, the nMOSFETs and pMOSFETs in FIG. 3 and FIG. 4 may also be swapped to create an alternative/dual representation. Such duality swapping should be familiar to people of ordinary skill in the art of MOSFET.

If the equivalent resistance of the select and/or by-pass transistors is non-negligible, such equivalent resistance can be estimated and incorporated into the calculation of the nominal current value for each test result, e.g., the true or false result for a == test operation. The word “equivalent” and “estimate” are used here because transistors have a nonlinear relationship between its V_{CG} and current, thus a changing resistance with respect to its bias conditions. The best estimation of such a transistor's equivalent resistance at the expected bias condition will result in the best estimation of nominal current, and hence how “distinguishable” various test results are among each other.

According to various embodiments, a method for performing == test operation using query input data against stored data may be provided,

where stored data are stored in resistive memory devices; and/or

where a “0” is stored as a (H L) pair, and a “1” is stored as a (L H) pair, where L denotes low-resistance state with resistance R_{L}, and H denotes high-resistance state R_{H}; and/or

where the 2m resistive elements of the 2m resistive memory devices are concatenated in series to form a NAND string; and/or

where each of the 2m resistive elements is connected with a MOSFET in parallel; and/or

where an m-bit == test operation is divided into m 1-bit == test operations, and a 1-bit == test operation involves generating a pair of voltages to the Gate terminals of the two MOSFETs corresponding to the pair of resistive elements being tested; and/or

where for the case of only nMOSFETs are being used for parallel connection to the resistive elements, for == “0”, a (hi, lo) voltage pair is used, and for == “1”, a (lo, hi) voltage pair is used, where hi is a voltage sufficiently high to make the nMOSFET turn ON, and lo is a voltage low enough to make the nMOSFET turn OFF; and/or

where the NAND string is applied a voltage drop of (V_{DD}−V_{SS}) and Id is the current flowing through the serial circuit of resistive elements, and == test operation is declared TRUE if and only if I≈(V_{DD}−V_{SS})/(m*R_{L}); and/or

where the “0” and “1” representations, the choice of nMOSFET vs. pMOSFET, are swapped according to the “duality” paradigm; and/or

where a (hi, hi) voltage pair is used to implement a query-side don't care bit; and/or

where a (L L) pair is used to implement a reference-side don't care bit.

According to various embodiments, various ways of implementing the interlocked design may be provided, augmenting it with essential hardware components, and extending it onto more versatile hardware architectures, in order to create a highly scalable, very low power fuzzy search system.

In the following, adaption of interlocked design to more hardware platforms according to various embodiments will be described.

In the following, adapting NOR flash cells to NAND flash architecture according to various embodiments will be described.

In the following, implementing NAND flash on standard logic CMOS process will be described.

The interlocked design may require modifying NAND Flash, thus requiring semiconductor process support for NAND Flash. However, native NAND Flash process support is not widely available, especially among semiconductor foundries. Therefore, it is desirable to effectively create NAND Flash process support from standard logic CMOS processes. Standard logic CMOS processes generally has at least 1 polysilicon (also known as poly) layer and supports MOSFETs of both n-channel and p-channel type.

Individual Flash cells have been created using standard logic CMOS processes, where the working principle is: (1) degenerate a pMOSFET into a capacitor by shorting its Drain, Source, Bulk; (2) connecting the Gate of the pMOSFET to the Gate of an nMOSFET using poly layer to form a floating gate (FG); (3) the shorted Drain, Source, Bulk of the pMOSFET then becomes the Control Gate (CG) of the newly formed Flash cell. This is illustrated in FIG. 5.

FIG. 5 shows an illustration 500 of a 2-Transistor Flash Cell based on standard logic CMOS process.

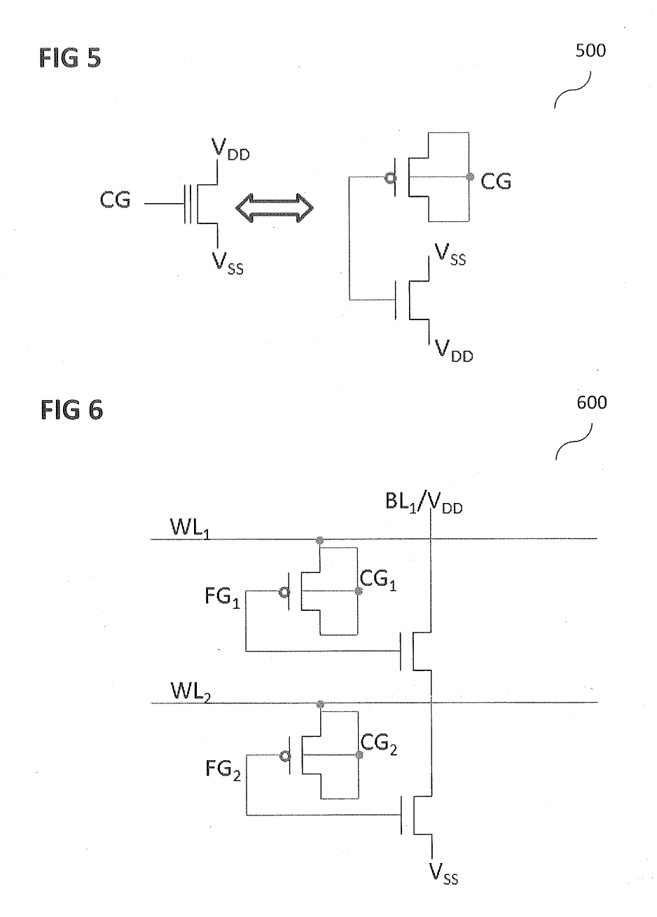

Commonly, only individual Flash cell operations or NOR Flash based operations are described. To create. NAND Flash out of such cells, FIG. 6 shows an embodiment example with one NAND string consisting of two. Flash cells, although a longer NAND string can also be created in the same manner. Also, additional NAND string(s) can be added to the side of the shown NAND string, so that all cells on the same word-line will be probed simultaneously.

FIG. 6 shows an illustration 600 of a 2-cell NAND string based on individual cell in FIG. 5. WL denotes Word-Line and BL denotes Bit-Line.

The cell in FIG. 5 may be programmed using either channel hot electron injection at nMOSFET (NCHE write), or Fowler-Nordheim (FN) tunneling at nMOSFET-side (NFN write); and it can be erased from either nMOSFET-side (NFN erase) or pMOSFET-side (PFN erase). The working principle is based on capacitive coupling between the capacitor in the degenerated pMOSFET (C_{gp}) and the implicit capacitor in the nMOSFET (C_{gn}), in order to produce the necessary voltages for write and erase, and to do so, the following criteria are used:

if α=C_{gp}/C_{gn}<1, NCHE write and PFN erase is used;

if 1<=α<=3, NCHE write and NFN erase is used;

if α>3, NFN write and NFN is used.

An NFN erase requires applying a high erase voltage at the Drain and Source of the nMOSFET, but the NAND string configuration in FIG. 5 implies that only the bit line and the other end of the NAND string can be applied external voltages. Therefore, on a long NAND string, all inside cells may not see a high enough voltage to achieve erase operation. This leaves only PEN erase as the erase option, which implies α<1 and NCHE write. However, NCHE write is hard to model analytically, hence may significantly increase the difficulty and non-recurring engineering (NRE) cost of creating a working circuit. Furthermore, NCHE write efficiency degrades in a NAND string configuration, especially for long NAND strings, making it a second-rate choice for NAND Flash based write operation. In comparison, NFN write which is tunneling based, is easily modeled analytically, but a criteria may requires α>3 to use NFN write, which conflicts with the condition of α<1 to use PFN erase.

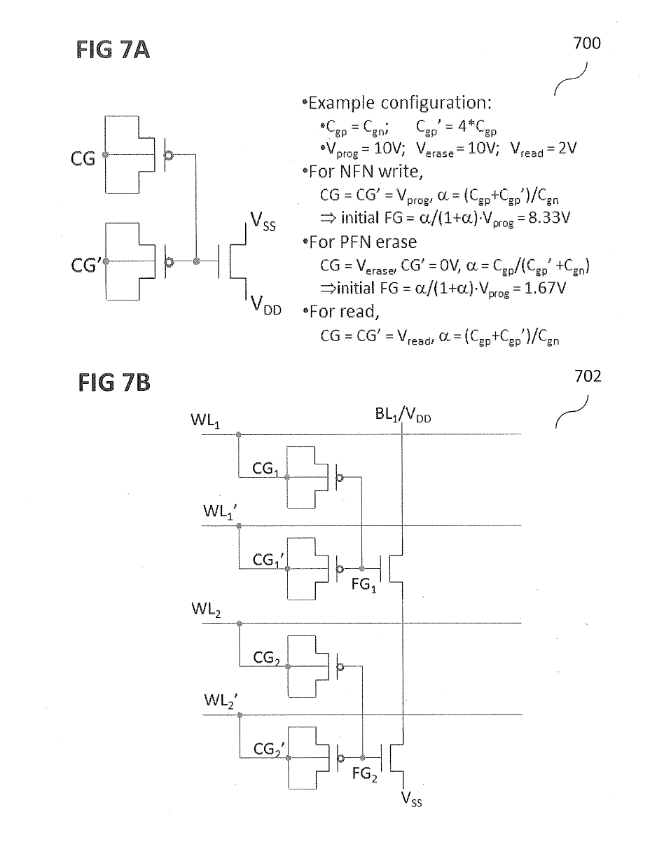

Therefore, it may be desirable to create a new type of Flash cell that can take advantage of both NFN write and PFN erase in a NAND configuration. This is illustrated in FIG. 7A, where 2 (instead of 1) pMOSFETs with independently controlled Control Gates are used to couple to the nMOSFET, with the additional pMOSFET preferably having a higher capacitance than the other MOSFETs in the same cell. When writing (using NFN tunneling), both Control Gates (CGs) are set to the same (or similar) high voltage V_{prog}, and Drain and Source of nMOSFET is set to 0V, resulting in a high coupling ratio from CGs to floating gate FG, and hence a high voltage at FG and hence a high electrical field between FG and nMOSFET channel, facilitating FN tunneling of electrons from nMOSFET channel to FG and thus programming the cell and raising the cell's threshold voltage Vₜₕ. When erasing, the CG of original pMOSFET is set to a high erase voltage Vₑᵣₐₛₑ, but CG of additional pMOSFET is set to a low voltage, preferably 0V, and Drain and Source of nMOSFET is set to 0V, resulting in a weak coupling ratio from first CG to FG, and hence a low voltage at FG and hence a high electrical field between FG and first CG, facilitating FN tunneling of electrons from FG to first CG and thus erasing the cell and reducing the cell's Vₜₕ.

FIG. 7A and FIG. 7B show NAND Flash based on standard logic CMOS process.

FIG. 7A shows an illustration 700 of a 3-Transistor Flash cell on standard logic CMOS process, allowing both NFN write and PFN erase.

FIG. 7B shows an illustration 702 of an example NAND Flash embodiment using FIG. 7A, with a NAND string length of 2 cells.

FIG. 7A shows such operation and gives example values of capacitors and voltages. The electrical field is the voltage drop between FG and the other terminal of FN tunneling, divided by thickness of the oxide or insulator in between. A field of around 10 MV/cm is strong enough to generate substantial FN tunneling. Therefore, to select an appropriate underlying CMOS process for implementing such. Flash cells, the oxide thickness (T_{OX}) of the MOSFETs must allow strong enough tunneling field, and-the oxide must be able to tolerate the corresponding electrical field. A typical 0.35 um standard CMOS process, for example, has a T_{OX} of around 7.7 nm, which in FIG. 7A's example configuration would lead to an initial 10.8 MV/cm field between FG and nMOSFET's Source, Drain and Channel, assuming FG is initially charge-neutral. As electrons tunnel to FG, both V_{FG} and the FN tunneling field will decrease and eventually stabilize. Conventional NAND Flash programming techniques, such as setting a program-inhibit voltage on unselected bit-lines, including the self-boosted program inhibit, may be used with the NAND Flash array based on the 3-Transistor cells illustrated in FIG. 7A and FIG. 7B.

For read operation, both CGs may use the same (or similar) voltage V_{read}, then it will have same or similar high coupling ratio as in the NFN write case, except V_{read} is generally noticeably smaller than V_{prog}. Also, in read mode the Drain of nMOSFET is set to a low voltage such as V_{dd} and Source of nMOSFET to Ground/0V. To implement multi-level cells (MLCs), multiple values of V_{prog} and corresponding V_{read} may be used. For interlocked based query operation, it is treated as if it were a read operation, except that each word-line may have its unique voltage, whereas in read for NAND Flash only the row being read has a voltage lower than a pass voltage, where the pass voltage is high enough to ensure conductance of the cell irrespective of the cell's state.

Of course, in program and read operations, voltages at CG and CG′ may be different, as long as it achieves the desired FN tunneling effect (for program) or accurate enough readout (for read). For erase operations, voltages at CG′ need not be 0V, as long as it achieves the desired erase effect. The voltages at Drain and Source of nMOSFET may also be adjusted from the nominal values described above, as long as the circuit still achieves the desired functionality. In addition, more than two pMOSFETs may be used for each such Flash cell, and by calculating the capacitive coupling from each pMOSFET to the cell's nMOSFET, a set of voltages for these pMOSFETs' CG in the cell may be determined to achieve the desired FN tunneling effect for program and for erase, using the same principle of high capacitive coupling ratio to V_{prog} during program, and low capacitive coupling ratio to Vₑᵣₐₛₑ during erase.

The trade-off of the above CMOS-based NAND Flash implementation includes a larger area per cell, because each pMOSFET in each such cell may require its own n-well, and the minimum spacing between n-wells in order to meet practically any CMOS process' design rule is substantial. This area penalty can be reduced by laying out the cells more efficiently, for example, using the approaches according to various embodiments described next.

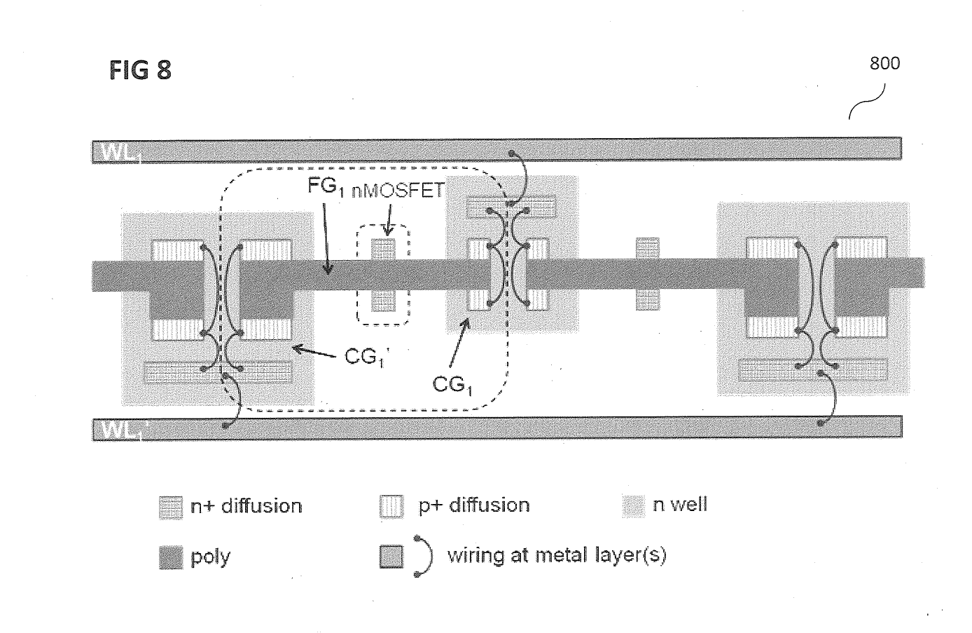

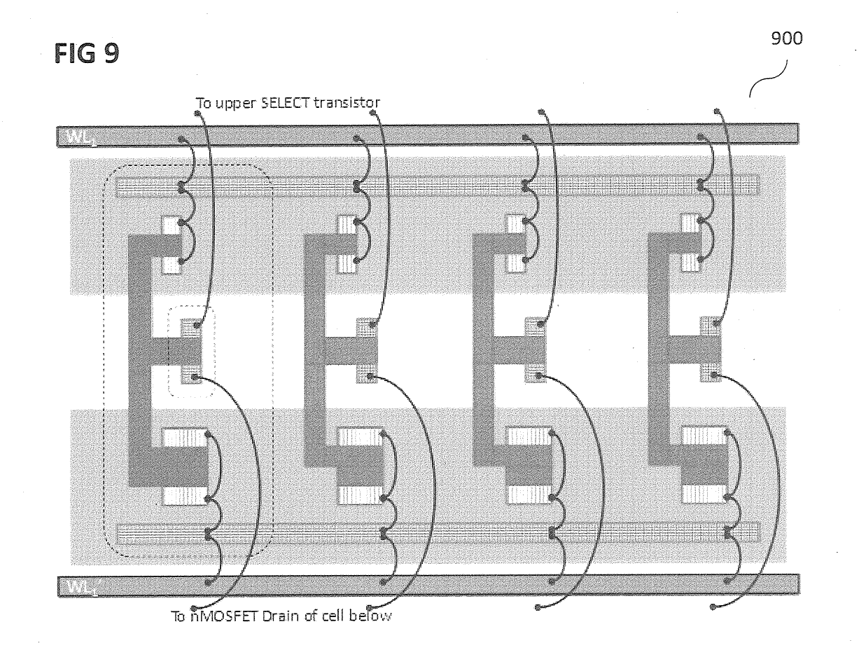

FIG. 8 shows an illustration 800 of one layout method for example Flash cell array based on 3-Transistor Flash cell in FIG. 7A and FIG. 7B; Metal layer wirings are drawn illustratively instead of strictly geometrically; Each dot at the end of a metal layer wiring arc represents a contact point, which would be a Via contact point if it is at a diffusion area.

FIG. 8 shows one embodiment example, by sharing an n-well between two adjacent cells on the same row. An n-well is shared by the additional pMOSFETs (CG′), and another n-well is shared by the original pMOSFETs (CG). A large dashed closure delineates the outline of one Flash cell, and a small dashed closure delineates the outline of one nMOSFET in this Flash cell. Note that to form a NAND string, another nMOSFET belonging to a Flash cell above the delineated cell can be concatenated to the nMOSFET in FIG. 8, either by elongating and merging the n+ diffusion between these two nMOSFETs, or by metal layer wiring to connect the Source of the higher up nMOSFET to the Drain of the lower nMOSFET. The positions, sizes and shapes of diffusions, poly lines, metal wires, etc. in FIG. 8 are for examples only, and other positions, sizes and shapes may be used while following the same approach of sharing n-wells between adjacent cells on the same row. The word-lines WL₁ and WL₁′ may also be poly wires (and preferably silicided to reduce resistance) or other conductive wires instead of metal wires. If WL₁ and WL₁′ etc. are at 2^{nd} poly layer (assuming a double-poly process is available), then the nMOSFETs' Drain and Source diffusions may be directly extended to connect adjacent cells in the same NAND string. If WL₁ and WL₁′ etc. are at 1^{st} poly layer, then the nMOSFETs' Drain and Source diffusions usually must use metal layer wiring to connect adjacent cells in the same NAND string, because 1^{st} poly layer is usually used as a self-aligned mask for n+ diffusions and WL₁ and WL₁′ would therefore “cut” the elongated n+ diffusions into two unmerged halves. It is to be noted that for ease of concept illustration, FIG. 8 is not drawn to scale to reflect the exact design rules of a given CMOS process since such rules may vary from process to process, but an actual layout should follow the corresponding design rules.

Another approach to reducing area overhead is by sharing the n-well across more than two (up to all) cells in a row, where multiple first pMOSFETs (CG) in a row share a horizontal n-well, and multiple second pMOSFETs (CG′) in a row share another horizontal n-well, as illustrated in FIG. 9.

FIG. 9 shows an illustration 900 of another layout for example Flash array based on cell in FIG. 7A-7B, with the same legends as in FIG. 8.

Because with this approach the nMOSFETs in the same column but in adjacent rows are now separated by the horizontal n-wells, metal layer wiring will be needed between such nMOSFETs in order to form a NAND string, as shown by the long wires in FIG. 9. FIG. 9 illustrates the example where WL₁ is the top word-line, and a string select transistor from higher up is connected to the nMOSFET at this word-line. If a different word-line were used in FIG. 9, then the upper long wires may go to nMOSFET Source of cell above. If the last word-line in a NAND string were used in FIG. 9, then the bottom long wires may go to a ground select transistor below it. The positions, sizes and shapes of diffusions, poly lines, metal wires, etc. in FIG. 9 are for examples only, and other positions, sizes and shapes may be used while following the same approach of sharing n-wells, one for first pMOSFETs (CG) and another for second pMOSFETs (CG′) among many (more than two and up to all) cells on the same row. In FIG. 9, the nMOSFETs are located between the two shared horizontal n-wells, but these nMOSFETs may also be placed above or below the two n-wells, which may then allow n+ diffusion based connection between nMOSFETs in adjacent cells on the same NAND string, although such connection cannot be extended beyond two adjacent cells without using metal layer wires. Note that for ease of concept illustration, FIG. 9 is not drawn to scale to reflect the exact design rules of a given CMOS process since such rules may vary from process to process, but an actual layout should follow the corresponding design rules.

In the following, implementing NAND Flash with 2-Transistor Source-Select (2TS) NOR Flash Cells according to various embodiments will be described.

Conventional NOR Flash based on 1-Transistor Flash cells can be re-arranged to a NAND layout to implement NAND Flash, assuming operating voltages can be adjusted accordingly and still fall within the safe ranges supported by the underlying NOR Flash semiconductor process. Some NOR Flash memories are based on a 2-Transistor Source-Select (2TS) Flash cell design, where 1 MOSFET serving as a select transistor connecting to the Source line and 1 floating-gate transistor serving as the storage element, forms a cell. The select transistor is used to deal with “over-erase” problem in NOR Flash, where an excessive erase may decrease a floating-gate transistor's Vₜₕ below the voltage applied to unselected rows (e.g., 0V), and cause unselected cells to drain current from the bit-line and interfere with the read-out of the select row's cell.

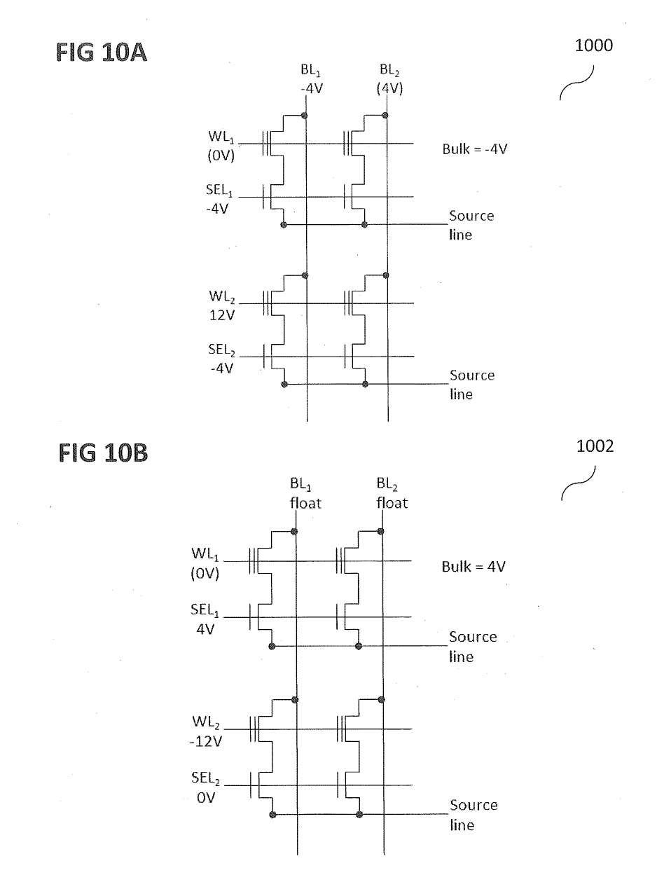

FIG. 10A and FIG. 10B show an example 2×2 NOR Flash cell array based on 2-Transistor Source-Select (2TS) Flash cell, with example operating voltages for (in FIG. 10A) programming the cell at the crossing of WL₂ and BL₁, or (in FIG. 10B) erasing the cells at WL₂. Note that voltages in ( ) indicate inhibited (i.e. unselected) columns or rows; Source line may be set to floating, i.e., not connected to any particular voltage, in both cases.

FIG. 10A shows an illustration 1000 of programming the cell at WL₂ and BL₁.

FIG. 10B shows an illustration 1002 of erasing the cells at WL₂.

FIG. 10A and FIG. 10B illustrates such a design with a 2×2 cell array, with example voltages shown for programming the cell located at the crossing of word-line 2 and bit-line 1. The −4V applied to the select transistor at SEL₁ reduces leakage current during cell programming, and the voltage (e.g. −4V) applied to the selected bit-line BL₁ (denoted V_{BL}_{_}ₛₑₗ) keeps the channel potential at the programmed floating-gate transistor at V_{BL}_{_}ₛₑₗ. Bulk is generally biased at V_{BL}_{_}ₛₑₗ or below, to prevent the P-N diode from turning on between Bulk and Drain of the programmed floating-gate transistor (which connects to the programming bit-line). To prevent cells in unselected rows from being programmed, voltage(s) on unselected word-lines (denoted V_{WL}_{_}ᵤₙₛₑₗ) are much lower than that of the selected word-line (denoted V_{WL}_{_}ᵤₙₛₑₗ), e.g. set to 0V. To prevent cells in unselected bit-lines from being programmed, voltage(s) on unselected bit-lines (denoted V_{BL}_{_}ᵤₙₛₑₗ) are higher than V_{BL}_{_}ₛₑₗ, e.g. set to 4V, and the channel potential of floating-gate transistor(s) on the selected word-line but not on the selected bit-line, will also be forced to V_{BL}_{_}ᵤₙₛₑₗ. This will reduce the electrical field between FG and Drain/Bulk of the unselected floating-gate transistor, and hence reduce undesired FN tunneling effects also known as program disturbs. With the availability of a select transistor for each cell, FIG. 10B shows it is possible to erase in the unit of a page (e.g., a row), instead of in the unit of a whole block of cell array. FN tunneling disturbs on unselected pages will be very small due to the relatively small voltage difference between unselected word-line(s) and Bulk. The voltages shown in FIG. 10A and FIG. 10B are examples only, and other voltages may be used to achieve desired cell programming and erasing functionalities. Note that for FIG. 10A and FIG. 10B and all figures thereafter, voltages in ( ) (brackets) indicate inhibited (i.e. unselected) columns or rows during programming or erasing.

If we assume a CG to FG coupling ratio CR of say 0.65, and a Tₒₓ of say 11 nm, the initial FG voltage (if the cell is initially charge-neutral) and initial FN tunneling field can be estimated as stated in Table 1.

TABLE 1
FN tunneling field for to-be-programmed cell and
unintended cells in 2-Tr NOR Flash of FIG. 10A
and FIG. 10B, assuming CR = 0.65 and Tₒₓ = 11 nm.

| | V_{FG} (initial) | Eₒₓ (initial) |
|---|---|---|
| Programmed Cell | V_{WL}_{_{—}}ₛₑₗ*CR + | (6.4 V − V_{BL}_{_{—}}ₛₑₗ)/ |
| | V_{BL}_{_{—}}ₛₑₗ*(1 − CR) = 6.4 V | Tₒₓ = 9.5 MV/cm |
| Gate Disturb | V_{WL}_{_{—}}ₛₑₗ*CR + | (9.2 V − V_{BL}_{_{—}}ᵤₙₛₑₗ)/ |
| (selected row, | V_{BL}_{_{—}}ᵤₙₛₑₗ*(1 − CR) = 9.2 V | Tₒₓ = 4.7 MV/cm |
| unselected column) | | |
| Drain Disturb | V_{WL}_{_{—}}ᵤₙₛₑₗ*CR + | (−1.4 V − V_{BL}_{_{—}}ₛₑₗ)/ |
| (unselected row, | V_{BL}_{_{—}}ₛₑₗ*(1 − CR) = −1.4 V | Tₒₓ = 2.4 MV/cm |
| selected column) | | |

In this case, Gate Disturb and Drain Disturb are fairly small, because FN tunneling current reduces exponentially with respect to tunneling field, and a reduction of 4 MV/cm in field (compared to the tunneling field in the to-be-programmed cell) will likely lead to a reduction in tunneling current by 10⁶ to 10⁸ times.

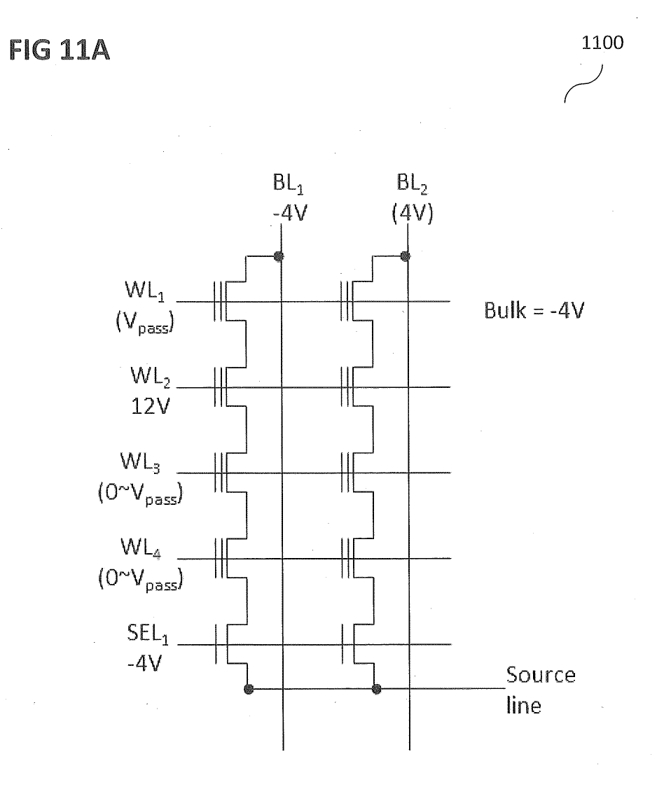

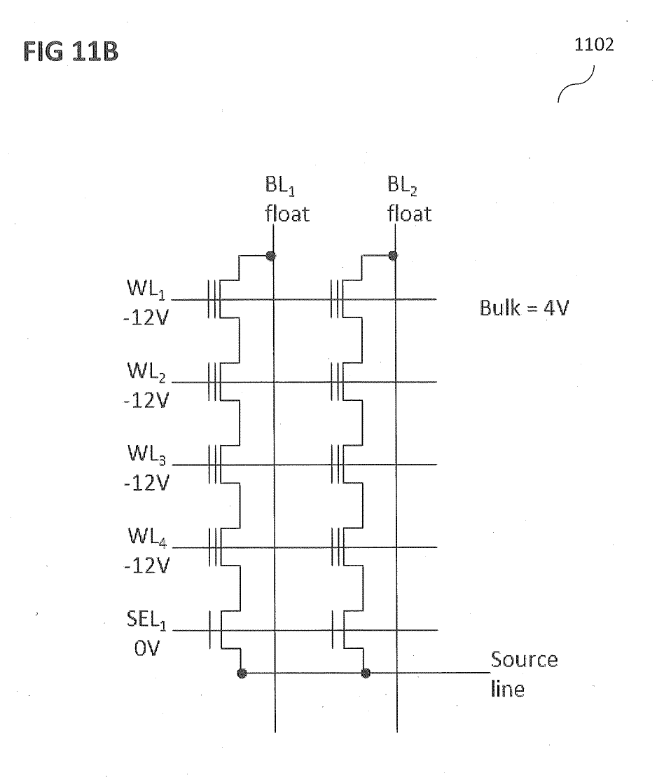

However, when adapting the above 2TS NOR Flash architecture to NAND, as illustrated in FIG. 11A and FIG. 11B, it will require the introduction of a new word-line voltage Vₚₐₛₛ) applied to unselected word-lines in the selected NAND string. The role of Vₚₐₛₛ is to ensure (a) all cells above the to-be-programmed cell and in the same column form a conducting channel; (b) all cells in any unselected column will maintain the channel potential at V_{BL}_{_}ᵤₙₛₑₗ, in order to reduce program disturbs; (c) Vₚₐₛₛ should not be too high to cause program disturbs on unselected rows. As described next these 3 requirements have certain contradictions, and may lead to undesirable operating conditions.

FIG. 11A and FIG. 11B show an adaption of 2TS NOR Flash cells to an exemplary 4×2 NAND array, with example operating voltages for (in FIG. 11A) programming the cell at the crossing of WL₂ and BL₁. (in FIG. 11B) erasing the cells in the entire selected NAND block. Note that voltages in ( ) indicate inhibited (i.e. unselected) columns or rows. Source line may be set to floating in both cases.

FIG. 11A shows an illustration 1100 of programming the cell at crossing of WL₂ and BL₁.

FIG. 11B shows an illustration 1102 of erasing the cells in the entire selected NAND block.

Especially, to meet requirement (b), the following must hold:

Vₚₐₛₛ×X CR+V_{BL}_{_}ᵤₙₛₑₗ×(1−CR)+ΔV_{prog}≦Vₜₕ_{_{—fg}}+V_{BL}_{_}ᵤₙₛₑₗ (1)

where ΔV_{prog} is the FG voltage at 0-bias when the cell is programmed (i.e., has an excess of electrons), and Vₜₕ_{_}_{fg} is the threshold voltage of the floating-gate transistor when viewed from the point of FG (instead of from the usual viewpoint of Control Gate CG), i.e., how much V_{FG}−V_{S} is needed to make its channel conduct. If we assume ΔV_{prog}=3V and Vₜₕ_{_}_{fg}=0.7V, then we get Vₚₐₛₛ≧9.7V. When this Vₚₐₛₛ is applied to the selected column, it will generate a fairly high tunneling field, causing strong program disturbs, as shown in Table 2 below.

TABLE 2
FN tunneling field for to-be-programmed cell and unintended cells
in NAND Flash made from 2-Tr NOR Flash cells in FIG. 10A and
FIG. 10B and Table 1; Eₒₓ calculated for Vₚₐₛₛ = 9.7 V.

| | V_{FG} (initial) | Eₒₓ (initial) |
|---|---|---|
| Programmed Cell | V_{WL}_{_{—}}ₛₑₗ*CR + | (6.4 V − V_{BL}_{_{—}}ₛₑₗ)/ |
| | V_{BL}_{_{—}}ₛₑₗ*(1 − CR) = 6.4 V | Tₒₓ = 9.5 MV/cm |
| Gate Disturb | V_{WL}_{_{—}}ₛₑₗ*CR + | (9.2 V − V_{BL}_{_{—}}ᵤₙₛₑₗ)/ |
| (selected row, | V_{BL}_{_{—}}ᵤₙₛₑₗ*(1 − CR) = 9.2 V | Tₒₓ = 4.7 MV/cm |
| unselected column) | | |
| Drain Disturb | Vₚₐₛₛ*CR + | (3.7 V − V_{BL}_{_{—}}ₛₑₗ)/ |
| (unselected row, | V_{BL}_{_{—}}ₛₑₗ*(1 − CR) = 4.9 V | Tₒₓ = 8.1 MV/cm |
| selected column) | | |
| Drain Disturb | Vₚₐₛₛ*CR + | (7.7 V − V_{BL}_{_{—}}ᵤₙₛₑₗ)/ |
| (unselected row, | V_{BL}_{_{—}}ᵤₙₛₑₗ*(1 − CR) = 7.7 V | Tₒₓ = 3.4 MV/cm |
| unselected column) | | |

As shown in Table 2, with the above assumed operating values, program disturb on unselected row in selected column will be 8.1 MV/cm, too close to the 9.5 MV/cm of the intended cells. Yet the requirement of Vₚₐₛₛ≧9.7V is needed to ensure the channel potential in unselected column(s) equalize to V_{BL}_{_}ᵤₙₛₑₗ. If Vₚₐₛₛ is reduced, there is either the likelihood of the channel potential on unselected columns) meeting V_{BL}_{_}ᵤₙₛₑₗ which may be needed to suppress program disturbs on unselected columns, or even worse, a lower Vₚₐₛₛ may have the effect of self-boosted program inhibit, which will increase channel potential on unselected columns to much higher than V_{BL}_{_}ᵤₙₛₑₗ. Although this will reduce program disturbs, it will raise both channel and drain/source potential, possibly to the point of junction breakdown. If it is required that no semiconductor process change (especially in junction voltage engineering) is needed (e.g. to reduce both NRE time and cost of process engineering), then a lower Vₚₐₛₛ cannot be used for chip reliability concerns.

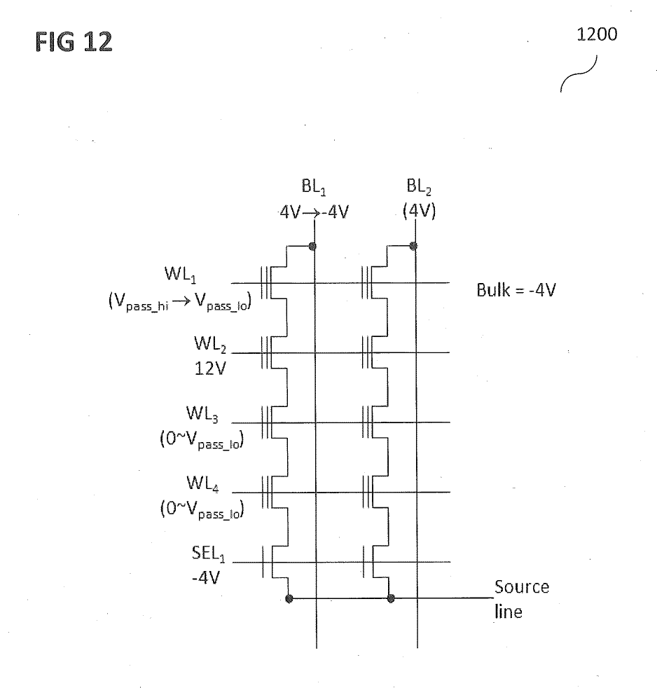

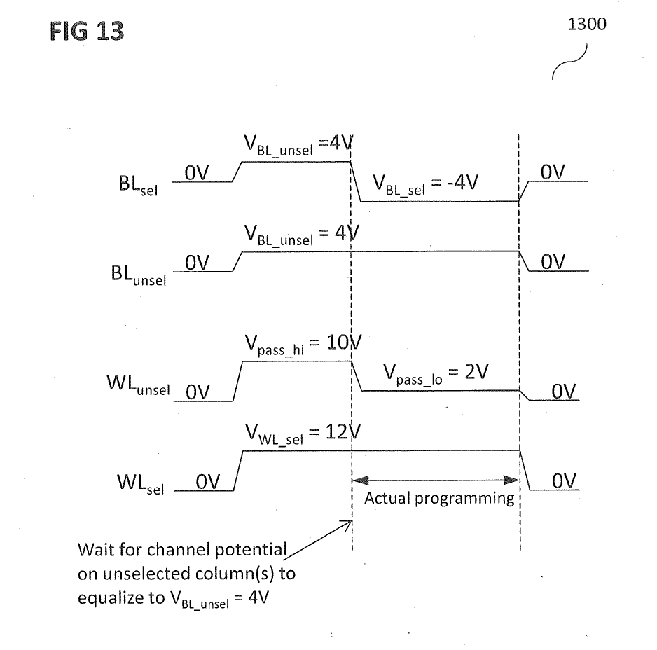

In the following, a way according to various embodiments to solve this problem will be described, as illustrated in FIG. 12 and FIG. 13.

FIG. 12 and FIG. 13 illustrate a method according to various embodiments for reducing program disturbs for NAND Flash adapted from 2TS NOR Flash cells requiring no process change, with operating conditions, time sequences, and example voltage values. Source line may be set to floating.

FIG. 12 shows an illustration 1200 of operating voltages for programming the row on WL₂, with BL₂ being inhibited (i.e. unselected) columns.

FIG. 13 shows an illustration 1300 of an example voltage timing sequence for selected row, selected column(s), unselected column(s), and the unselected row(s) that are above the selected row.

Instead of always using a high Vₚₐₛₛ, we first apply a Vₚₐₛₛ hi which meets equation (1), e.g. 10V, and also apply V_{BL}_{_}ᵤₙₛₑₗ (or a voltage noticeably higher than V_{BL}_{_}ₛₑₗ) to the selected bit-line, and wait for the channel potentials on unselected column(s) to stabilize to V_{BL}_{_}ᵤₙₛₑₗ (or whatever voltage the selected bit-line is hereby first applied). Then, reduce the voltage(s) on unselected row(s) from Vₚₐₛₛ_{_}ₕᵢ to a Vₚₐₛₛ_{_}ₗₒ which meets Vₚₐₛₛ_{_}ₗₒ×CR+V_{BL}_{_}ₛₑₗ×(1−CR)+ΔV_{prog}≧Vₜₕ_{_}_{fg}+V_{BL}_{_}ₛₑₗ, e.g. 2V, and also increase the selected bit-line's voltage to V_{BL}_{_}ₛₑₗ, and wait for the actual cell programming to take place. By applying V_{BL}_{_}ᵤₙₛₑₗ to the selected bit-line, program disturb field is reduced to only ˜3.4 MV/cm, and after the channel potentials on the unselected column(s) stabilize/equalize to V_{BL}_{_}ᵤₙₛₑₗ, then Vₚₐₛₛ_{_}ₗₒ and V_{BL}_{_}ₛₑₗ are applied, and the program disturb field on unselected row, selected column would still be kept reasonably low, e.g. in this case to ˜3.5 MV/cm if Vₚₐₛₛ_{_}ₗₒ=2V. When Vₚₐₛₛ reduces from Vₚₐₛₛ_{_}ₕᵢ to Vₚₐₛₛ_{_}ₗₒ, due to capacitive coupling the channel potentials on unselected column(s) may also decrease, but such decrease will neither cause appreciable increase in unwanted tunneling field because FG to channel voltage drop will generally decrease due to capacitive coupling, nor lead to any junction breakdown since the junction voltage drop will only decrease when channel potential decreases. For word-lines below the selected row, the voltages may be set to a value≦Vₚₐₛₛ_{_}ₗₒ, so that the cells on these word-lines do not get noticeable program disturbs. Note that the voltage values shown in FIG. 11A-11B, 12 and 13 are examples only, and other voltages may be used to achieve desired cell programming and erasing functionalities by following the concept just described.

In the following, implementing NAND Flash with SS-CHE Split-Gate (1.5-Transistor) NOR Flash Cells according to various embodiments will be described.

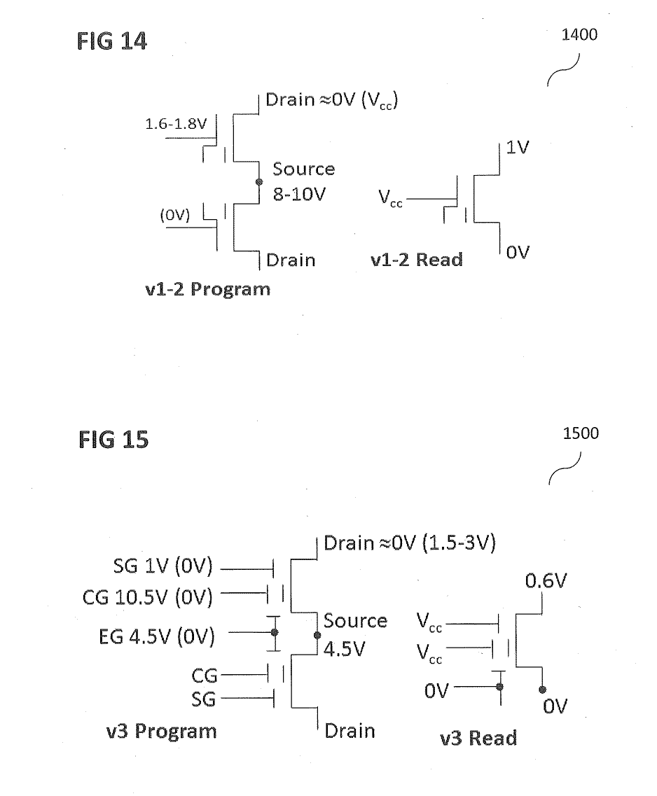

Another important type of NOR Flash design is the split-gate, also known as 1.5-Transistor cell design, where half of the cell functions as a select transistor, and the other half as the floating-gate transistor. Such design generally uses the much more power-efficient Source-Side Channel Hot Electron (SS-CHE) injection (also known as Source-Side Injection or SSI) for cell programming. FIG. 14 and FIG. 15 illustrate the operating conditions of SS-CHE split-gate cells, with SuperFlash as an example.

FIG. 14 and FIG. 15 show example operating conditions of SS-CHE split-gate NOR Flash cells, with SuperFlash as the illustrating example; V_{cc} is typically the supply voltage; The values in ( ) denote voltages to be used on unselected word-lines or bit-lines.

FIG. 14 shows an illustration 1400 of SuperFlash v1 and v2.

FIG. 15 shows an illustration 1500 of SuperFlash v3 with addition of Erase Gate (EG) and Control Gate (CG).

In all SS-CHE split-gate NOR Flash cell designs, there is a word-line gate immediately on top of the channel at the. Drain side, and a floating gate immediately on top of the channel at the Source side. To program such a cell, a high voltage V_{S}_{_}_{pgm}_{_}_{NOR} is applied at the Source and a V_{D}_{_}_{pgm}_{_}_{NOR}≈0V is applied at the Drain, and the word-line is applied a V_{WL}_{_}_{pgm}_{_}_{NOR} which slightly turns on the channel immediately beneath the word-line gate. V_{D}_{_}_{pgm}_{_}_{NOR} may also be generated by a small current source instead of being a fixed voltage. During read, V_{ref1}, typically V_{cc}, is applied to the word-line, and V_{ref2}, usually around 1V, is applied to the bit-line, which is the Drain side of the cell. In SuperFlash v3, as illustrated in FIG. 15, the word-line gate is further split into a select gate SG (which may still be called word-line gate), and a control gate CG which is on top of the floating gate, and an additional erase gate EG is added to facilitate erasing data. EG is shared between a pair of adjacent SuperFlash v3 cells, as shown in FIG. 15.

In the following, low-power techniques for implementing interlocked design according to various embodiments will be described.

In the interlocked design, a NAND string conducts only if its represented data pattern matches the query data pattern. The presence (or lack of) of the. NAND string's conductive state can be measured by a sense-amplifier. Any sense-amplifier designed for conventional NAND Flash read operation may be used, since all such sense-amplifiers are designed to test whether a NAND string conducts. For low-power operation, voltage-based sense-amplifiers may be preferable to current-based sense-amplifiers, since no reference current is needed in a voltage-based sense-amplifier, and having a reference current for each column/bit-line may incur non-negligible power overhead. A voltage-based sense-amplifier may work by first pre-charging the measured NAND string's belonging bit-line to a pre-defined voltage Vₚᵣₑ (e.g. V_{cc}), then float the bit-line from the Vₚᵣₑ input, and then apply corresponding word-line voltages to test NAND string conductivity by checking whether the bit-line's voltage has decreased to below a certain level. If the string is not conductive, the bit-line voltage will still be almost the same as Vₚᵣₑ. If the string is conductive, the bit-line will gradually discharge to ground and its voltage will measurably decrease by the end of the sensing time window. One such voltage-based sense-amplifier uses a double-inverter based latch, where the pre-charging stage forces the latch to an initial state, and if the NAND string conducts and bit-line discharges, once beyond the trip point of the inverter, the latch will toggle and reach a new bi-stable state. Therefore the latch state corresponds to the NAND string's conductivity state.

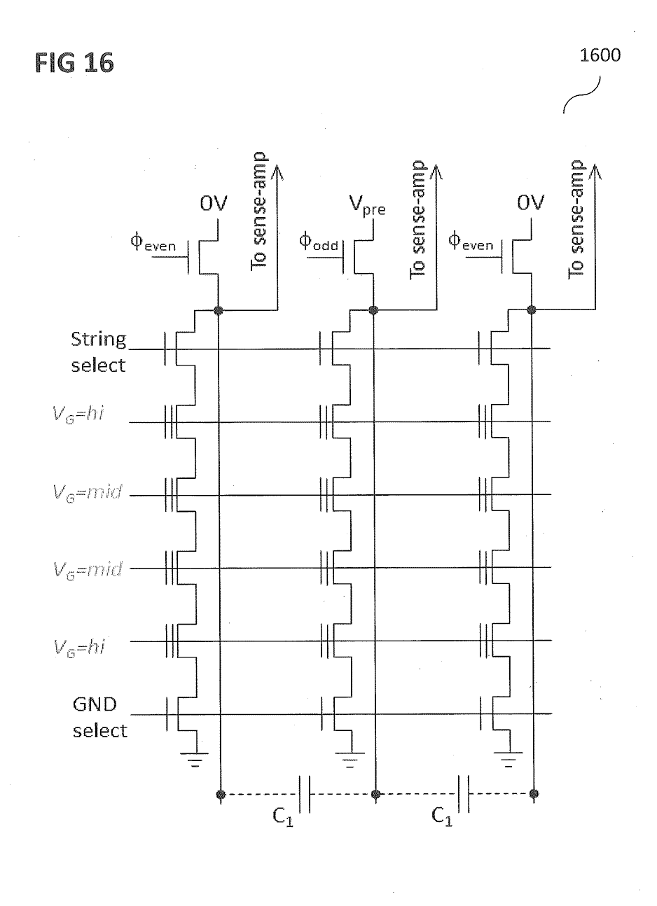

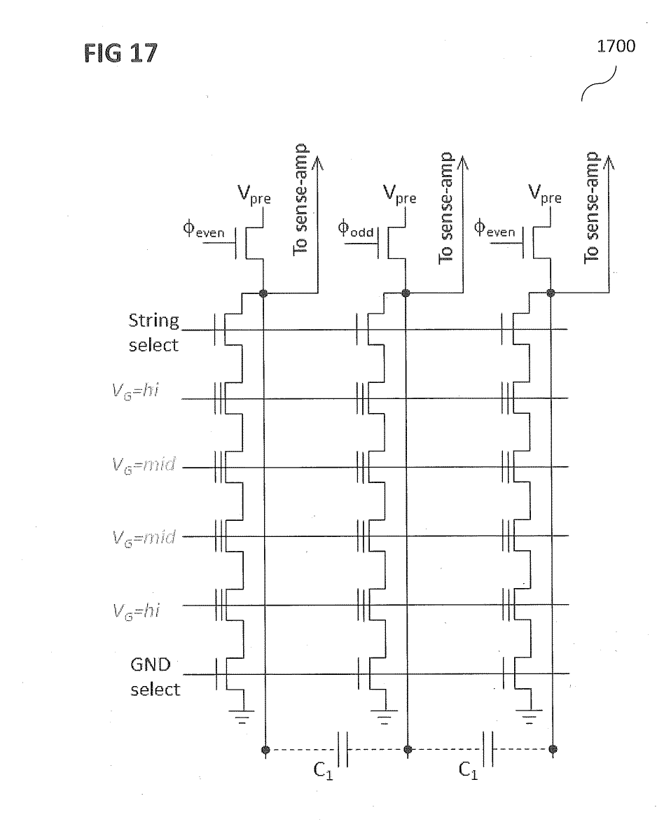

FIG. 16 and FIG. 17 illustrate a shielded bit-line sensing method and its modification for low-power sensing, example given for sensing the odd bit-line(s). In conventional scheme (as illustrated in FIG. 16), φ_{odd} is high during pre-charging, then low to “float” the bit-line and activate the word-lines to test any discharge on the bit-line, whereas φₑᵥₑₙ may be held high during both pre-charging and sensing; In modified scheme according to various embodiments (as illustrated in FIG. 17), when sensing odd bit-lines, the even bit-lines are also initialized to Vₚᵣₑ and held at such voltage to achieve shielding. C₁ denotes parasitic capacitance between adjacent bit-lines. Here word-line voltages correspond to an interlocked query sub-pattern of “01” if using the convention in FIG. 2.

FIG. 16 shows an illustration 1600 of a conventional method (a ground shielding scheme).

FIG. 17 shows an illustration 1700 of a modified method according to various embodiments (a Vₚᵣₑ level shielding scheme).

Due to potentially high parasitic capacitive-coupling interference between adjacent bit-lines in NAND Flash, the Shielded Bit-line sensing method may be used to suppress such interference, by pre-charging and then sensing the even bit-lines first while simultaneously grounding all odd bit-lines, followed by pre-charging and then sensing the odd bit-lines first while simultaneously grounding all even bit-lines (or vice versa). As illustrated in FIG. 16, this reduces interference between adjacent bit-lines, and interference from non-adjacent bit-line(s) is much smaller. To save transistors, the same sense-amplifier is typically shared between a pair of even and odd bit-lines. However, this scheme will always discharge all even or odd (and typically both even and odd) bit-lines by grounding them. This means the energy spent on pre-charging the even and/or odd bit-lines are lost during grounding/shielding. It also defeats the low-power purpose of the interlocked design, because instead of a matching bit-line consuming energy (through the discharging of its bit-line), at least half (and typically all) bit lines will consume energy by pre-charging then discharging these bit-lines. To avoid this overhead, the All-Bit-Line (ABL) architecture may be used, where all bit-lines (whether even or odd) are sensed simultaneously. Then, all the bit-lines are pre-charged to Vₚᵣₑ, and during ABL-based sensing only matching bit-lines will discharge, and at the next matching operation, all the bit-lines will be pre-charged again, but only those bit-lines that matched in the previous matching operation will need re-charging and consume energy, resulting in low-power sensing for pattern matching. Note that in ABL architecture, current sensing instead of voltage sensing may be preferred due to speed and accuracy, and in such case, the pre-charge voltage Vₚᵣₑ in current sensing is typically lower than the Vₚᵣₑ used in voltage sensing, and the bit-lines may need to be held at Vₚᵣₑ for a brief time (as opposed to simply discharging in voltage sensing) due to technical implementation requirement of current sensing.

If Shielded Bit-line sensing has to be used instead of ABL architecture, the shielding scheme can be modified from ground-shielding to pre-charge level shielding to make it low-power. That is, when pre-charging and sensing the even bit-lines, the odd bit-lines are also pre-charged to the same pre-charge voltage Vₚᵣₑ; but during sensing the odd bit-lines will be held at the Vₚᵣₑ input, instead of being floated from the Vₚᵣₑ input and tested for any discharge as in the even bit-lines. Assuming that most bit-lines don't match the query input, then only very few odd bit-lines will draw current during sensing. Then, when pre-charging and sensing the odd bit-lines, the even bit-lines are also pre-charged to Vₚᵣₑ, but will be held at the Vₚᵣₑ input, instead of being floated from the Vₚᵣₑ input and tested for any discharge as in the odd bit-lines. This is illustrated in FIG. 17. Assuming that most bit-lines don't match the query input, then only very few shielding bit-lines will draw current during sensing. However, to further reduce such current draw, one may allocate a pair of interlocked Flash cells either in each NAND string or in each bit-line, and such pair on any even bit-line may store a represented “0”, and on any odd bit-line may store a represented “1”. The query input pattern can then be augmented with an additional pattern bit with the same value as the value representing the even/odd bit-line denomination that is to be sensed, i.e., in this case with a “0” when sensing the even bit-lines and with a “1” when sensing the odd bit-lines. Then, the shielding bit-lines need not be held at Vₚᵣₑ, because the query input pattern will not match them. In addition, with such augmented pattern bit, when sensing the even bit-lines, knowing that the odd bit-lines cannot discharge, φ_{odd} may use the same signal as φₑᵥₑₙ, i.e., φ_{odd} may be low during sensing so that the odd bit-lines are floated after pre-charging to Vₚᵣₑ. Similarly, when sensing the odd bit-lines, φₑᵥₑₙ may use the same signal as φ_{odd}, i.e., φₑᵥₑₙ may be low during sensing so that the even bit-lines are floated after pre-charging to Vₚᵣₑ. Therefore, φₑᵥₑₙ and φ_{odd} may be the same signal and hence may be laid out as a single word-line (simpler layout and smaller chip area) as opposed to two separate word-lines. Also, in Shielded bit-line sensing scheme one sense-amplifier may be shared by two (one even, one odd) bit-lines, sometimes even by an additional two bit-lines from its neighbor array. Our pre-charge level shielding method and FIG. 17 will still work in the presence of such sharing, by noting that instead of each up-pointing arrow in FIG. 17 going to a separate sense-amplifier, each pair of adjacent up-point arrows in FIG. 17 will go to a separate sense-amplifier, and that the corresponding sense-amplifier may further be pointed to by another two such arrows in a neighbor array. Of course, the opposite convention may also be used, by “0” representing all odd bit-lines and “1” representing all even bit-lines. Also, such a pair of cells may be MLCs representing more than 2 values, but only 2 different values are needed for the above modified shielding scheme.

In the following, adapting interlocked design to NOR Flash architecture will be described.

Although the interlocked design may be based on NAND Flash, in the following, a method of adapting it to NOR Flash architecture according to various embodiments will be described. Instead of only a matching NAND string's bit-line will conduct and draw current, with the NOR adaptation only a mismatching column's bit-line will conduct and draw current, and consequently only a matching column's bit-line will not draw current.

In the following, a 1-bit Case (and extension to Next-Generation Memories) according to various embodiments will be described.

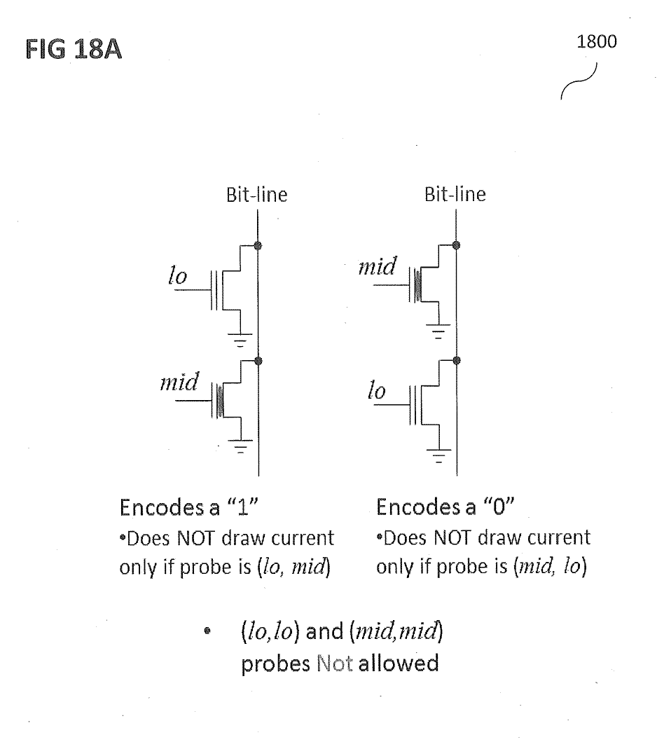

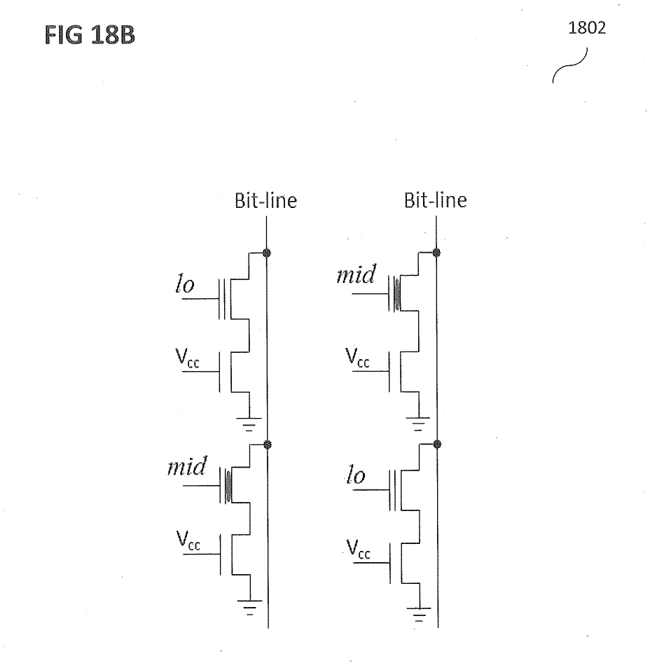

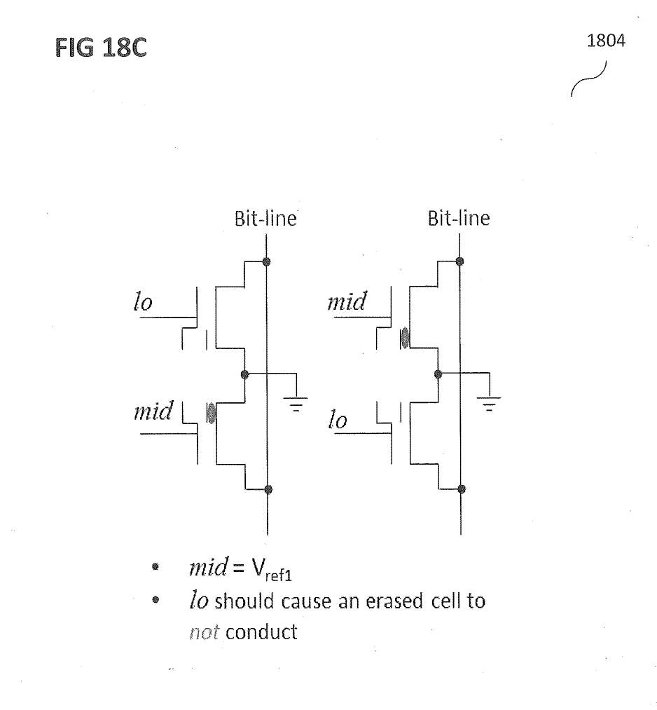

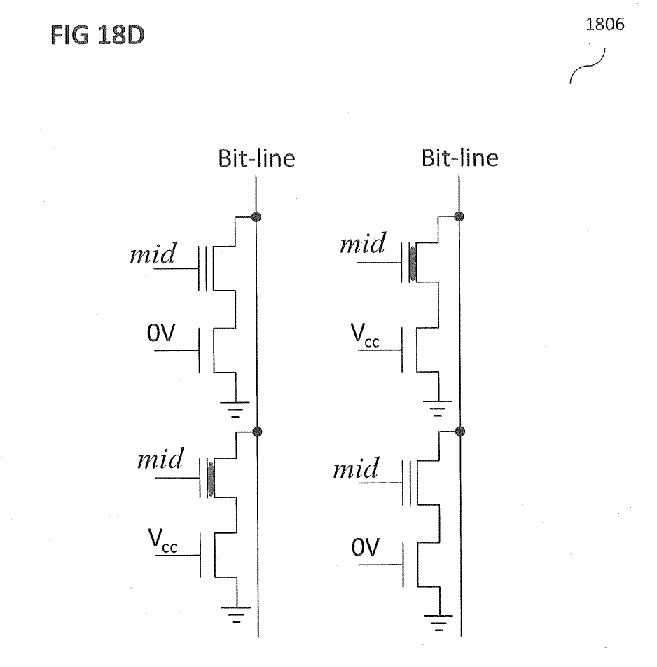

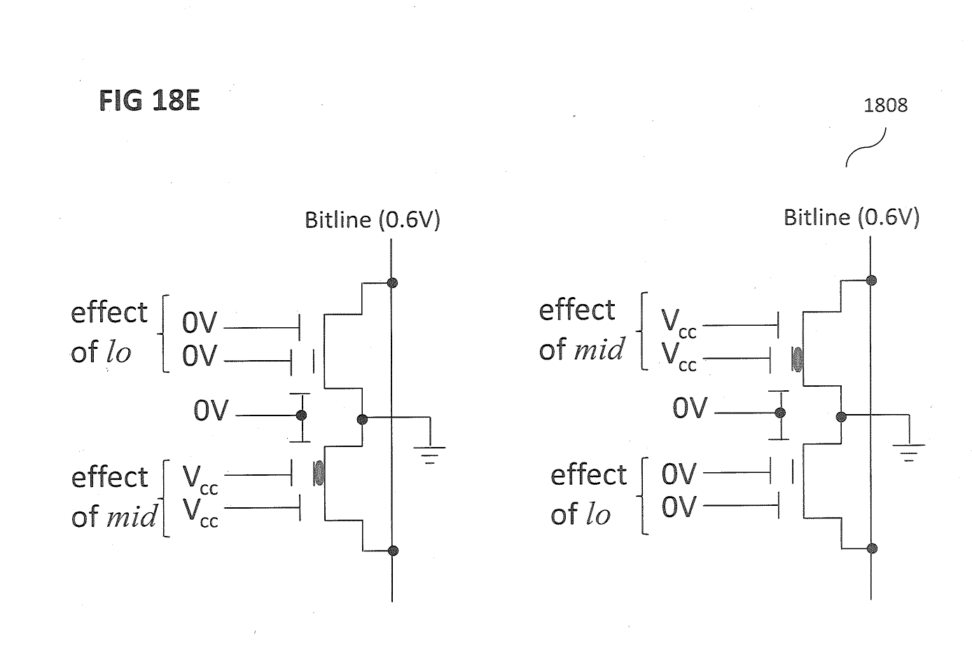

FIG. 18A, FIG. 18B, FIG. 18C, FIG. 18D, and FIG. 18E illustrate adapting the 1-bit NAND-Flash based interlocked design as described above to NOR Flash. As in FIG. 2, for ease of drawing, a solid-filled ellipse beside the floating gate (FG) denotes negative charge that is present on a programmed cell, although in practice the charge resides on the FG itself. The bit-line may be at V_{cc} or V_{dd} or any appropriate voltage for sensing, and is typically pre-charged to such voltage and then tested for discharge, as described above, or by steady-state current sensing. V_{ref1} in FIG. 18C may be as defined above.

FIG. 18A shows an illustration 1800 of adapting to 1-Tr NOR Flash.

FIG. 18B and FIG. 18D shows an illustration 1802 and an illustration 1806 of adapting to 2TS NOR Flash in FIG. 10A and FIG. 10B, respectively.

FIG. 18C and FIG. 18E shows an illustration 1804 and an illustration 1808 of adapting to SuperFlash v1-2 and v3 in FIG. 14 and FIG. 15.

FIG. 18A, FIG. 18B, FIG. 18C, FIG. 18D, and FIG. 18E show the adaptation of 1-bit interlocked design in FIG. 2 to NOR Flash. Instead of having two voltages called mid and hi, two voltages called lo and mid are used, where the value of mid may be the same as in the NAND case (i.e. mid is able to make an erased cell conduct but not make a programmed cell conduct), while lo is a voltage lower than mid such that lo must cause an erased cell not to conduct. As seen from FIG. 18A, FIG. 18B, FIG. 18C, FIG. 18D, and FIG. 18E, a (erased, programmed) cell pair is used to represent/encode a “1”, and to test “== 1”, a probing voltage pair (lo, mid) is applied to the control gates (word-lines) of the pair of cells. If the stored encoding is “1”, then the cell pair will not conduct (i.e., neither of the two cells will conduct). If stored value is “1” and (mid, lo) is applied, then top cell will conduct, and bottom will not conduct. As shown in FIG. 18A, FIG. 18B, FIG. 18C, FIG. 18D, and FIG. 18E, a (programmed, erased) cell pair is used to represent/encode a “0”, and to test “== 0”, a probing voltage pair (mid, lo) is applied. So if (lo, mid) is applied to cell pair with stored encoding “0”, then bottom cell will conduct, and top cell will not conduct. Similarly, if stored encoding is “0” and (mid, lo) is applied, then neither cell will conduct. FIG. 18A shows the case of adapting 1-Tr NOR Flash to interlocked design. FIG. 18B shows adaptation for 2TS NOR Flash such as in FIG. 10A and 10B, where gates of all Source-side Select transistors involved in pattern matching are applied a high enough turn-on voltage, e.g. V_{cc}, and the control gates (i.e. word-lines) of the floating-gate transistors corresponding to these Select transistors are still applied the same voltages as in the 1-Tr NOR Flash case like in FIG. 18A, i.e. a (erased, programmed) cell pair represents/encodes a “1”, and to test “== 1”, a probing voltage pair (lo, mid) is applied to the control gates (word-lines) of the pair of cells, and a (programmed, erased) cell pair is used to represent/encode a “0”, and to test “== 0”, a probing voltage pair (mid, lo) is applied. The case of FIG. 18B is thus also referred to as 2TS NOR Flash default. Furthermore, because the voltage lo may be negative and possibly inconvenient to generate, in 2TS NOR Flash, as shown in FIG. 18D, only mid voltage may instead be applied to both word-lines of a cell pair, whereas a low enough turn-off voltage, e.g. 0V, may be applied to the gate of the top Source-side Select transistor in the cell pair iff it would have been applied a lo voltage in the case of FIG. 18B, and whereas a high enough, turn-on voltage, e.g. V_{cc}, may be applied to the gate of the top Source-side Select transistor in the cell pair iff it would have been applied a mid voltage in the case of FIG. 18B. Then, it would achieve the same effect of FIG. 18B, without requiring a lo voltage. The case of FIG. 18D is thus also referred to as 2TS NOR Flash with mid-only voltage to word lines.

Read and query sensing can be done by either voltage, or current. If by voltage, generally the bit-line is pre-charged to a given level Vₚᵣₑ (typically V_{cc} or V_{dd}), then the bit-line is floated from Vₚᵣₑ, and the word-lines are probed with corresponding voltages, and the sense amplifier tests for presence of discharge on the bit-line to determine presence of current flow, same as explained above. Alternatively, current based sense amplifiers, such as described above may be used.

Although FIG. 18A, FIG. 18B, FIG. 18C, FIG. 18D, and FIG. 18E only show examples with one pair of cells on a bit-line, additional cell pair(s) may be added to a column by connecting each cell's Drain terminal to the bit-line (just like in conventional NOR Flash architecture), and to perform a pattern match, probing voltage pairs corresponding to the query pattern are applied to the word-lines of corresponding cell pairs. Only if the pattern completely matches, then the bit-line will not draw current.

Because each bit-line of a typical NOR Flash cell array may attach many cells, for cell pair(s) not participating in a particular pattern match, then their corresponding word-lines should be applied low enough voltage(s) (e.g. lo) to guarantee non-conductivity in the cell channel irrespective of the cell state, so that they don't contribute bit-line current spuriously. For example, if there are 32 cell pair(s), i.e. 64 cells attached on a bit-line, and query pattern corresponds to only top 16 bits, then the bottom 16 cell pairs' word-lines can all be applied lo. In addition, for 2TS NOR Flash (e.g. FIG. 18B), all cell pair(s) not participating in a particular pattern match may also have their select transistors' gate(s) applied low enough voltage(s) (e.g. 0V) to guarantee non-conductivity in the channel of every select transistor, especially if over-erase of cells is a concern and would have otherwise contributed spurious bit-line current.

By treating SuperFlash v1-2 cells as if they are 2TS NOR Flash cells like in FIG. 18B, we can adapt the interlocked design to it as well. This is illustrated in FIG. 18C, where v_{ref1} in FIG. 18C is defined as the word-line read voltage of SuperFlash, typically V_{cc}, where in FIG. 18C the left cell pair encodes/represents a “1” and its gate voltages implements a “== 1” test, and the right cell pair encodes/represents a “0” and its gate voltages implements a “== 0” test. For SuperFlash v3, there are select gate (SG), control gate (CG) and erase gate (EG) for each cell, with EG shared within a cell pair. To adapt interlocked design to SuperFlash v3, the conventional read condition in v3 (e.g. SG=CG=V_{cc}, EG=0V) has the equivalent effect of mid in FIG. 18C, and to create an equivalent lo effect in v3, one or more of SG, CG and EG voltages need to be reduced, e.g. to SG=CG=EG=0V. Then, the same approach in FIG. 18C can be applied to v3. This is illustrated in FIG. 18E, with example operating voltages, where in FIG. 18E the left cell pair encodes/represents a “1” and its gate voltages as an example implements a “== 1” test, and the right cell pair encodes/represents a “0” and its gate voltages as an example implements a “== 0” test. Of course, there may exist multiple voltage combinations of SG, CG, EG that has the equivalent effect of lo and mid, and any such combination may be used to implement NOR version of interlocked design for SuperFlash v3.

Weak bits, also known as don't care bits, can also be implemented in the NOR adaptation of interlocked design. A (programmed, programmed) cell pair may be used to implement a reference-side weak bit, because both (lo, mid) and (mid, lo) will not be able to make either of the two cells conduct, thus designating a matched query bit. Although not allowed in FIG. 18A in non-weak-bit matching, a (lo, lo) probing voltage pair may be used to implement a query-side weak bit, because neither cell will conduct with such input irrespective of its cell state. When using a (lo, lo) query-side weak bit in 2TS NOR Flash adaptation in FIG. 18B, the select transistors may be applied low enough voltage(s) (e.g. 0V) to deal with over-erase concern. A (mid, mid) may be used to implement a query-side anti-match bit, that is, it will always be a mismatch because it will draw current on at least one of the two cells (unless the cell pair is a reference-side weak bit). When using a (mid, mid) query-side anti-match bit in 2TS NOR Flash adaptation in FIG. 18B, the select transistors should be applied high enough voltage(s) (e.g. V_{cc}) so that the select transistors does not become a barrier to current flow.

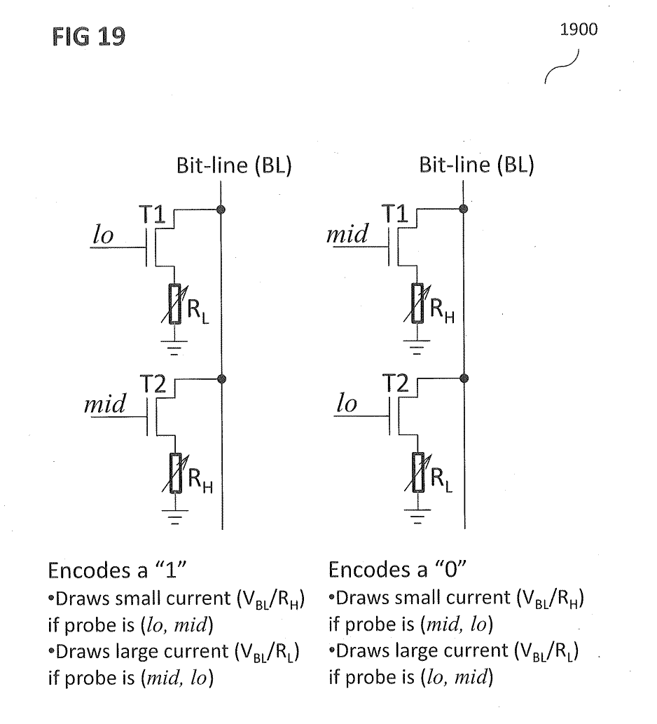

FIG. 19 shows an illustration 1900 of an adaption of 1-bit interlocked design to next-generation memory which also has a NOR-type architecture. lo should not cause a select transistor to conduct (e.g. 0V), and mid should cause a select transistor to conduct (e.g. V_{cc}).

In addition to adapting the interlocked design to NOR Flash architecture, it can also be adapted to next-generation memories (NGMEM), such as PCRAM (Phase Change), RRAM (Resistive), and MRAM (Magnetic). The basic characteristic of NGMEM is a programmable resistor connected in series to a select transistor, where the resistance state (low resistance vs. high resistance) may be changed by applying certain signals (e.g. voltages or for MRAM a current with a certain electron spin) on the bit-line. As illustrated in FIG. 19, R_{H} and R_{L} designate the high and low resistance value of the programmable resistor storage element in such a memory cell. Actual R_{H} and R_{L} may follow a probabilistic distribution instead of being a single value. In addition to the arrangement in FIG. 19, the programmable resistor may also reside on the Drain (Bit-line) side of the select transistor. As seen from FIG. 19, a matching cell pair will draw only a small current of V_{BL}/R_{H}, whereas a mismatched cell pair will draw a large current of V_{BL}/R_{L}. As in the case in NOR Flash, for cell pair(s) not participating in a pattern match, their corresponding word-lines should be applied low enough voltage(s) such as lo, so that these cells do not contribute bit-line current spuriously.

In addition, a (R_{H}, R_{H}) cell pair may be used to implement a reference-side weak-bit, because it will draw a small current of V_{BL}/R_{H} per cell pair, irrespective of input (lo, mid) or (mid, lo). Similarly, a (lo, lo) may be used to implement a query-side weak-bit, because it will always draw no current. However, this no current more accurately speaking is the cell leakage current when applied (lo, lo), and is almost zero, which makes it slightly different from V_{BL}/R_{H} (the match current for 1 cell pair without query-side weak-bit) especially when R_{H}is not very large, therefore the sense amplifier may need to take into account the existence of query-side weak-bit to use a proper reference current level for sensing.

In the following, a multi-bit and range query case according to various embodiments will be described.

To extend the interlocked design of NOR Flash to multi-level cells (MLCs), for convenience of description, we use the opposite encoding convention to FIG. 18. So 0 designates an erased cell, a larger number designates a more programmed cell (i.e. with more negative charges on the floating gate), and 2^{l}−1 designates a most programmed cell, where the cell is l-bit. To encode a pattern value of i, a cell pair of (i, 2^{l}−i−1) may be used. To test for “== i”, an interlocked query pattern of (i, 2^{l}−i−1) may be used, which is then transformed to a voltage pair of f(i), f(2^{l}−i−1), where f(i) is a monotonic increasing function of i, and also satisfying f(i)>=Vₜₕ (i−1) && f(i)<Vₜₕ (i), where Vₜₕ(i) is the threshold voltage (as seen from the control gate or word-line) of a cell with state i. For robustness, f(i) may be defined as (Vₜₕ(i)+Vₜₕ(i−1))/2, and for i=0, f(i) should be substantially lower than Vₜₕ(0), so that f(0) will not cause any erased cell to conduct.

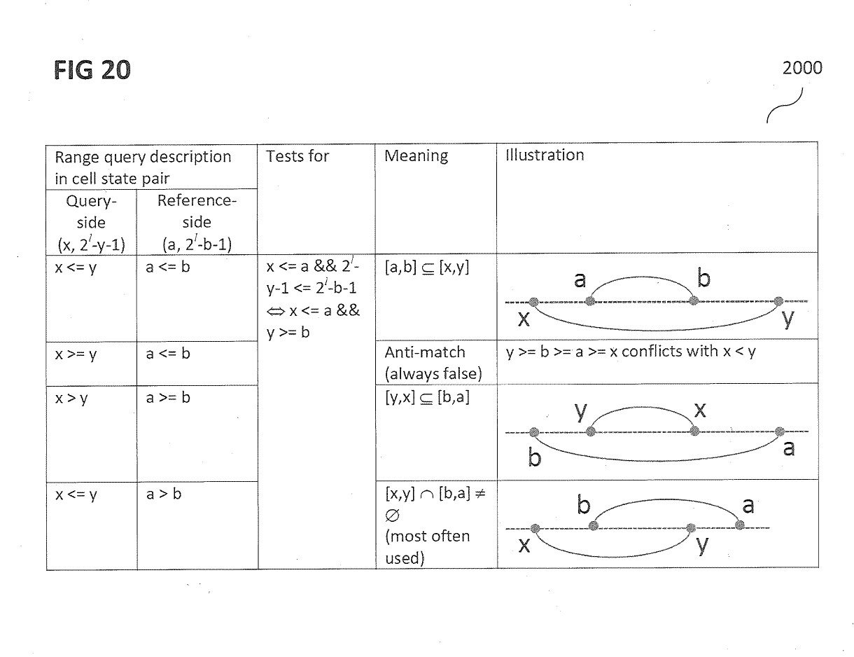

Then, it can be proven that the above scheme implements the multi-bit exact match for NOR Flash, including for l=1. More generally, if the reference cell pair is (a, 2^{l}−b−1), and the query pair is (x, 2^{l}−y−1), then it is testing for the expression x≦a && y≦b. This may be used to implement complex search functionalities such as range query, similar to the range query, but with different mappings, because the direction of the inequality operators for x vs. a, and y vs. b may be opposite compared to those commonly used. The mappings for NOR Flash is illustrated in FIG. 20.

FIG. 20 shows an illustration 2000 of types of range queries in an l-bit fGT MLC pair and their semantic meanings.

Also, instead of an l-bit cell, more generally a k-state cell may also be used, simply by replacing 2^{l} with k in the interlocked notation for l-bit cell, including various, forms of range query in FIG. 20.

Again, for cell pairs not participating in the pattern match, their corresponding word-lines should be applied a low enough voltage, e.g. f(0), such that none of these cells can conduct irrespective of their cell states.

Although a monotonically increasing f(i) is used in this section, monotonically decreasing f(i) may also be used provided the cell state definition is reversed such that state 0 is the most programmed and state 2^{l}−1 is erased. Also, instead of n-channel Flash cells which are the default here, p-channel Flash cells may also be used. P-channel Flash cells implements a <=logic instead of n-channel's >=logic. The conversion of this section's NOR Flash interlocked design to p-channel Flash can be done following the same procedures for porting NAND Flash interlocked design to p-channel Flash, and should be familiar to those skilled in the art of p-channel Flash. Similarly, notation convention of what encodes/represents a “0” vs. “1”, and what probing voltages corresponding to a query test of “== 0” vs “== 1”, may be swapped for FIG. 18A-18E and FIG. 19 to produce a dual version of interlocked design for NOR Flash and NGMEM. In all these adaptations, e.g. FIG. 18A-18E, 19, 20, and even including the k-state generalizations, the commonality is that the voltages applied to gates of the cell pair make the cell pair into high resistance mode when the query pattern matches the stored pattern and into low resistance mode when the query pattern does not match the stored pattern.

With the NOR adaptation of the interlocked design, most columns would have current flow because most columns will likely be mismatched, and this could lead to significantly higher power consumption compared to the. NAND version of the interlocked design. To curb power consumption, one may use type(s) of sense-amplifier(s) with early mismatch detection, i.e., detecting a mismatched column (which would have a relatively high mismatch current) early on in the sensing cycle and then immediately cut off current flow to such a column.

In the following, interlocked design without double storage requirement according to various embodiments will be described.

The interlocked design and its extension to NOR-Flash architecture described above all use two l-bit (or more generally k-state) cells to represent an l-bit (or more generally k-state) value or range. According to various embodiments, a method of using only one cell instead of two cells may be provided to achieve the same functionality of == test without actually reading the cells. That is, if the == test is false, the accessing circuit does not necessarily know what value is stored in those cells. This “not necessarily know” characteristic is similar to the interlocked design and its extension to NOR-Flash as described above.

In the following, a NOR flash case according to various embodiments will be described.

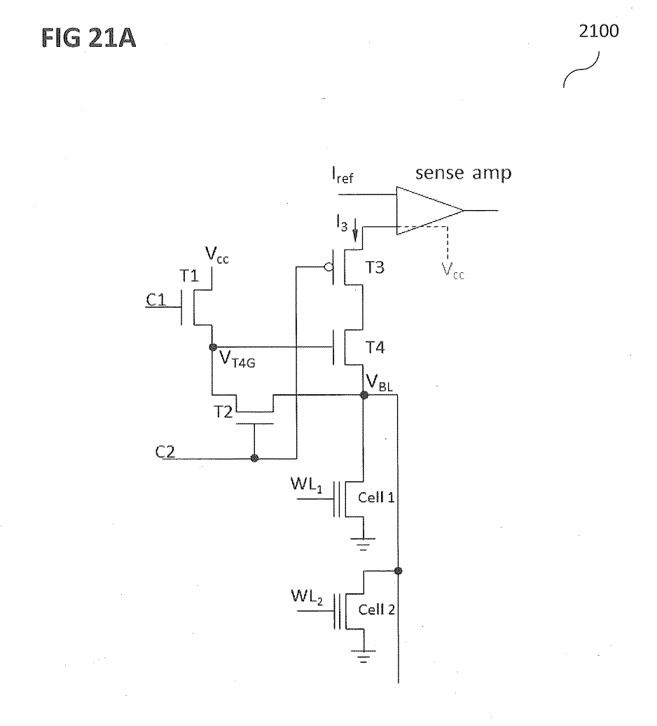

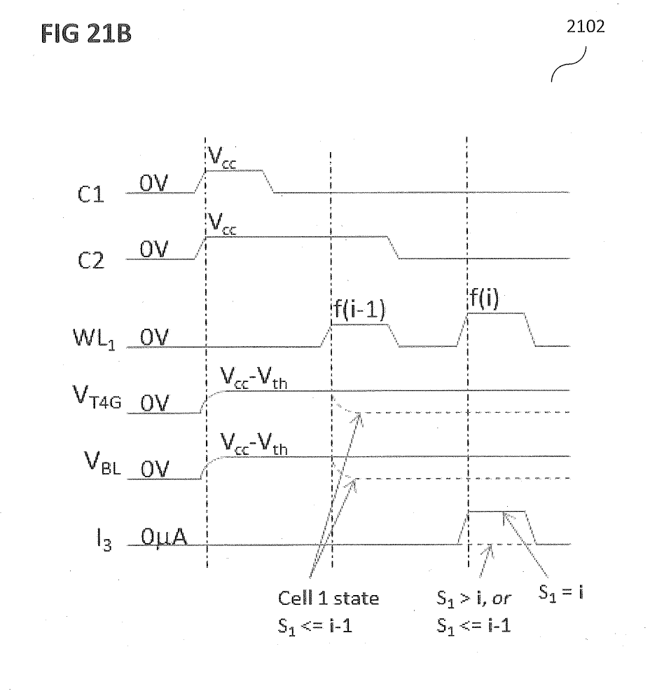

FIG. 21A and FIG. 21B illustrate a circuit for implementing interlocked design on NOR Flash without the doubled storage requirement. Note the current-based sense amplifier's 2^{nd} input from transistor T3 may implicitly connect to V_{cc} (shown in dashed line) in order to create a flowing current from T3 to the probed cells which can be compared by the sense amplifier against a reference current I_{ref}. Cell state 0 designates erased cell, and f(i) is a voltage that will turn cell with state i on but not state i+1 on, f(i) typically may be (Vₜₕ(i)+Vₜₕ(i+1))/2.

FIG. 21A shows an illustration 2100 of a read/query sensing circuit according to various embodiments.

FIG. 21B shows an illustration 2102 of a signal timing diagram for accessing cell 1 on WL₁.

FIG. 21A and FIG. 21B illustrate this method with circuit schematic. Its working mechanism is similar to dynamic logic. Signal C1 pre-charges T4's Gate (V_{T4G}) close to logic high level, typically V_{cc}−Vₜₙ due to Vₜₙ loss of nMOSFET T1. Note here Vₜₙ is the threshold voltage of the nMOSFETs, not of the Flash cells. Note the threshold voltages of Flash cells with state i is described by function Vₜₕ(i), distinguished from Vₜₙ with both a different subscript name and a state index. Similarly, C2 pre-charges the bit-line V_{BL} also to V_{cc}−Vₜₙ. Then C2 is held high while C1 is held low, and to probe cell 1, word-line WL₁ is applied a voltage of f(i−1), which will be just enough to turn on cells with state <=i−1. Note here f(i) is enough to just turn on a cell with state i but not turn on a cell with state i+1, same as the baseline definition, whereas above, a different f(i) is defined such that f(i) is enough to just turn on a cell with stated-1 but not state i.

The f(i−1) pulse of WL₁ will drain the bit-line's pre-charged level from V_{cc}−Vₜₙ to 0V, if cell 1 state (denoted S₁) is i−1 or smaller, because the cell would have conducted. Because C2 is still held high, the draining/discharging of the bit-line will also cause the parasitic capacitor at Gate of T4 to discharge, also from V_{cc}−Vₜₙ to 0V. This implies T4 will not turn on afterwards (until the next read/query cycle). Note while C2 is held high, the pMOSFET T3 will remain off.

After the f(i−1) pulse of WL₁ and any potential discharging of bit-line and T4G is complete, C2 is then held low (which would turn on T3), and WL₁ is applied a voltage of f(i), so if cell state S₁>i, the cell will not conduct. If S₁=i the cell will conduct, and since C2 is now low implying T2 is now off, V_{T4G} will remain at V_{cc}−Vₜₕ instead of discharging to 0V, keeping T4 on. Then conducting current I₃ is compared against a reference current I_{ref} by a current-based sense amplifier, which can then report a logic output of whether I₃>I_{ref}. Because I₃ requires a voltage source, an implicit V_{cc} may be contained inside the sense-amplifier, as illustrated by the dashed line FIG. 21A.

The method in FIG. 21A and FIG. 21B may be extended to query-side range query. To test whether a cell's state S ∈ [x,y], its corresponding word-line (e.g. WL₁ in case of FIG. 21A and FIG. 21B's example) is first applied f(x−1), then applied f(y) and tested for presence of current. If S<=x−1, then the bit-line and T4G would have discharged, and when f(y) is applied the bit-line will not draw current because T4 will be turned off If S>y, then when f(y) is applied the cell will not conduct and the bit-line will not draw current either. Only if S ∈ [x,y], will the cell conduct and the bit-line draw current.

FIG. 21A and FIG. 21B illustrate 2 cells attached on one bit-line but only shows the operation of probing one cell/word-line at a time, but it is also possible to probe multiple word-lines simultaneously. For cell j on row/word-line j, if =qᵢ test is to be performed, where qᵢ is the state value in the query sub-pattern at line j, then WLⱼ can be first applied f(qⱼ−1), then applied f(qⱼ), and tested for presence of current. Each cell j, if it passes the == qⱼ test, will contribute to the bit-line current. If such contribution is roughly the same for every match cell j, and if per matching cell's bit-line current is approximated as I₀, then for m matching cells, the total bit-line current≈m·I₀. One practical challenge is to determine whether all probed cells matched, because for m probed cells, a difference between m·Iₒ and (m−1)·I₀ is only I₀, which may be relatively small to distinguish in a current-based sense amplifier.

Similar to range query for one cell, multiple cells can also be probed with query-side range query. To test whether a cell j (on row j)'s state Sⱼ ∈ [xⱼ,yⱼ], its corresponding WLⱼ can be first applied f(xⱼ−1), then applied f(yⱼ) and tested for presence of current. Compared to the more strict == qⱼ test, a range query is not only more relaxed in matching constraint, but also may generate a more diverse (i.e. more widely distributed) levels of matching current. This is because for any == i test, if f(i)=(Vₜₕ(i)+Vₜₕ(i+1))/2, then the word-line voltage is exactly ΔV/2 higher than Vₜₕ(i), where ΔV=Vₜₕ(i+1)−Vₜₕ(i), and ΔV is typically same or similar for all i's. This implies that the conducting/matching current will be similar across all i's, e.g. I₀. Whereas in range query, during 2^{nd} WL pulse, if matched, WLⱼ−Vₜₕ(Sⱼ) may be much higher than ΔV/2, and the matching current may be much higher than I₀. Or, the matching current may be just I₀. Then, the total bit-line current where all m cells match may span from (m−1)·I₀ to much higher, and where m−1 cells match may span from (m−1)·I₀ to much higher, and note the two current ranges will generally overlap. Therefore, it may become challenging to accurately determine whether all m cells matched.

In the following, a NAND flash case according to various embodiments will be described.

For NAND Flash, the 1^{st} WL pulse has to be applied to each word-line without overlapping in time. In addition, when applying the 1^{st} WL pulse of voltage f(xⱼ−1) on row j, then all other word-lines must be supplied a hi voltage where hi must ensure cell conductance irrespective of cell state. If the bit-line did not discharge after testing all probed cells in the 1^{st} WL pulse, then it can be concluded that Sᵢ>=xⱼ. Then, when applying the 2^{nd} WL pulse of voltage f(yᵢ) on row j, all probing word-lines can be applied simultaneously instead of sequentially. Then, if the bit-line conducts, it can be concluded that Sⱼ<=yⱼ, hence Sⱼ ∈ [xⱼ,yⱼ]. The disadvantage of this method for NAND Flash is the long delay, a random access cycle required for each probing word-line during the 1^{st} WL pulse.

In the following, a memory architecture suitable for writing data in column-wise manner according to various embodiments will be described.

In applications where the fuzzy search database does not change frequently, conventional write operations, e.g., writing in page-wise manner where a page is generally a row of memory cells, may be used. However, in cases where the database needs to change or update frequently, especially if the reference data patterns become available in a real-time streaming fashion, it maybe more time-efficient to write data in a column-wise manner, because waiting for reference data patterns to accumulate to the point of filling the whole memory array may incur undesirable latency. Next we show how to adapt NOR, NAND and next-generation memory architectures, so that reference data patterns can be written to the array in a natively column-wise manner. In addition, such native support may also support column-wise erase or reset operations natively, so that the database may be updated in-place incrementally, without having to erase an entire block before updating (a limitation usually found in NAND and NOR Flash memories).

In the following, adaption for SuperFlash v1-2 NOR Type according to various embodiments will be described.

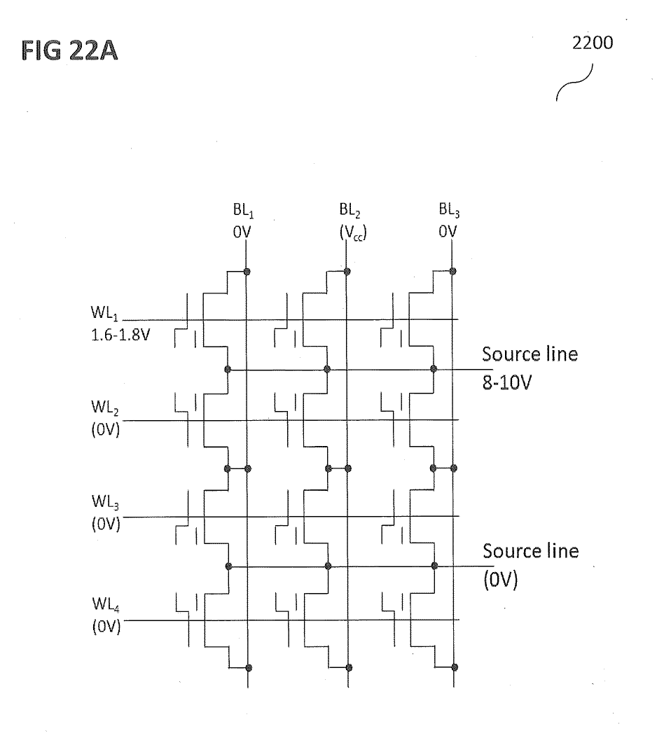

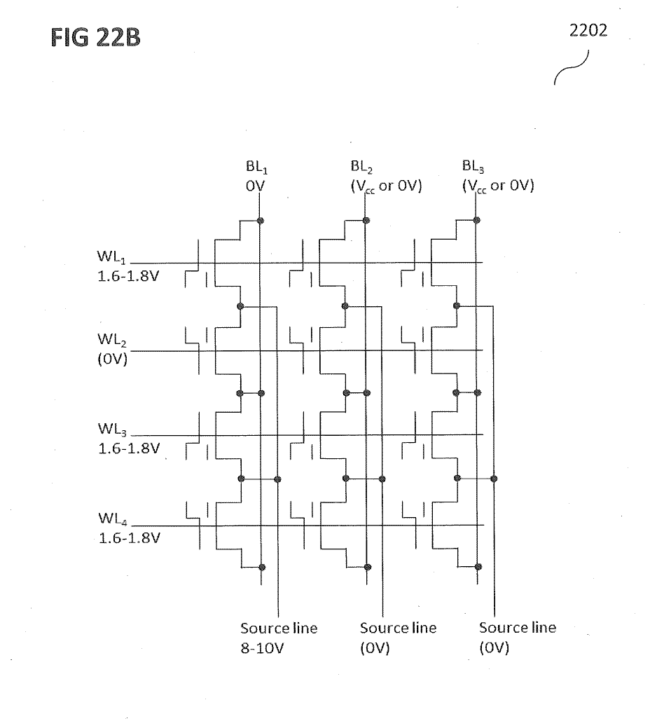

In conventional SuperFlash v1 and v2, in the cell array Source diffusions in the same row are typically extended and merged together to form a Source line, and only up to 1 row of cells are programmed at a time, with the selected row's Source line applied 8-10V and other Source lines applied 0V, as illustrated in FIG. 22A.

FIG. 22A and FIG. 22B illustrate a comparison of conventional (row-wise) and new (column-wise) cell programming method, with example 4×3 cell array and example operating voltages. Voltages in ( ) mean program inhibit, i.e., unselected columns or rows.

FIG. 22A shows an illustration 2200 of cell programming (row-wise) in conventional SuperFlash v1-2; Cells on WL₁, specifically at BL₁ and BL₃ are programmed.

FIG. 22B shows an illustration 2202 of a cell programming method according to various embodiments (column-wise) in Adapted version of SuperFlash v1-2; Cells on BL₁, specifically at WL₁, WL₃ and WL₄ are programmed.

In the adapted architecture, in the cell array a Source line is merged from Source diffusions in the same column, and each word-line may be applied a non-0V voltage for programming, and the column selected for programming is applied a bit-line voltage of ˜0V, and other bit-lines are applied V_{cc} to inhibit programming on unselected columns. This is illustrated in FIG. 22B. Such concept of merging source diffusions in the same column can be extended to SuperFlash v3 as well.

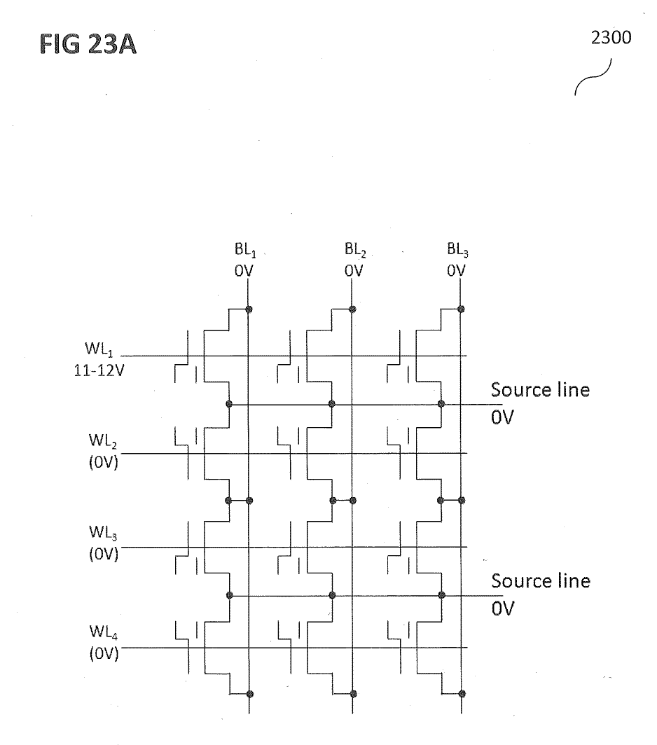

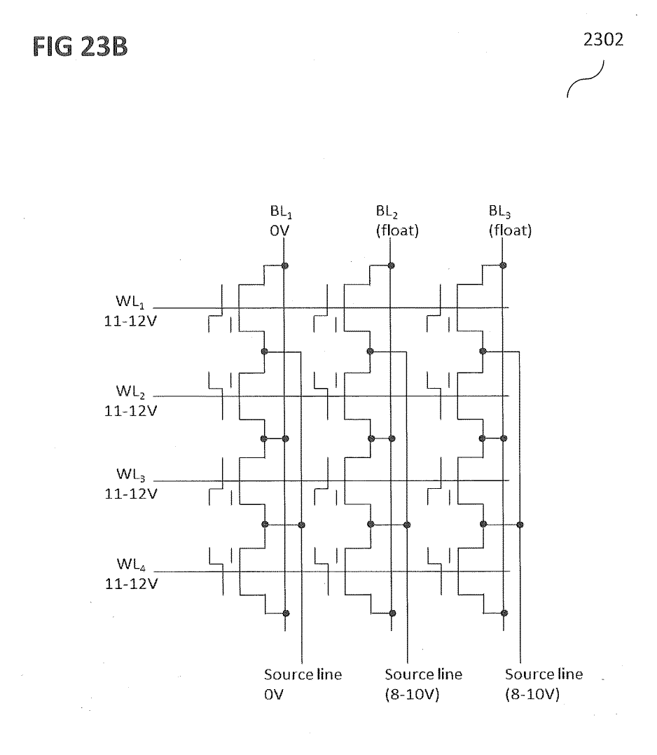

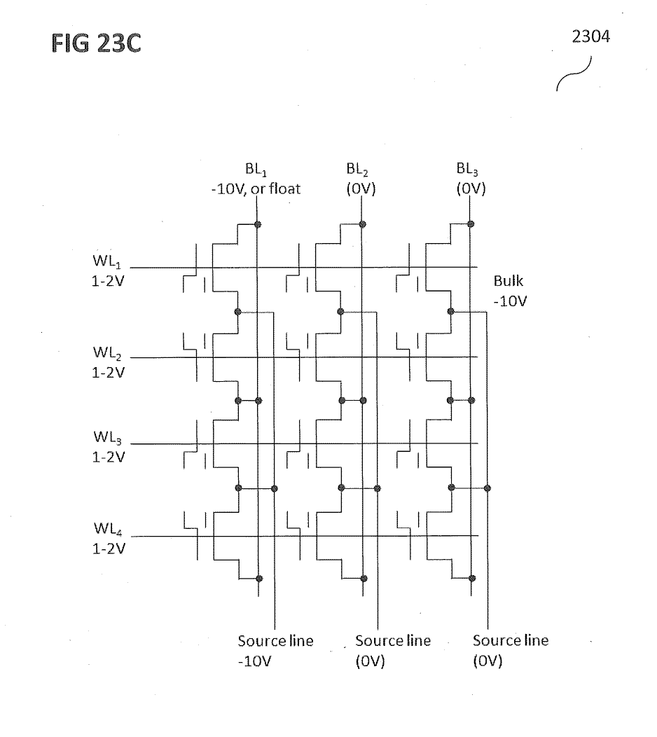

If each Source line can be independently controlled, then conventional SuperFlash would allow page-wise (row-wise) erase, as opposed to having to erase by the whole block. When adapted to the simultaneous column-wise programming method illustrated in FIG. 22B, because the Source line is merged per column, it accordingly allows column-wise erase, provided each Source line can be independently controlled. This means not only incremental insertion/appending operation is allowed on the database of reference data patterns, but also in-place update operations. Because WL is high voltage (i.e. V_{WL}_{_}_{pgm}_{_}_{NOR} as described herein) during erase in SuperFlash v1-2, so we need to inhibit programming on unselected columns, and one way is to supply all unselected columns' Sources with a high voltage, e.g. 8-10V (i.e. V_{S}_{_}_{pgm}_{_}_{NOR} as in described herein, which would not require additional junction voltage engineering), so that Sources will couple to its corresponding FGs to a relatively highly voltage (due to typical high coupling ratio between Source and FG) to inhibit erase due to FN enhanced tunneling. Such approach is illustrated in FIG. 23B, but it is power-inefficient due to the need to feed high voltage to many places. However, SuperFlash typically has triple well support, so it may be possible to bias the P-well (which is where the cell array is placed) at a substantially negative voltage V_{well}, e.g. −10V (or at least −V_{S}_{_}_{pgm}_{_}_{NOR} if no additional junction engineering is wanted), and the selected Source line also at a negative voltage no lower than V_{well}, e.g. −10V, and unselected Source lines at a voltage much higher than V_{well} e.g. 0V, float the bit-lines, and bias the WL at a small voltage e.g. 0V, then for the selected cell (on the selected column/Source line) its FG will see a relatively negative voltage due to high capacitive coupling from its Source and thus creating a relatively large voltage drop between FG and WL, facilitate tunneling. On unselected cells, because Source is 0V, it will form a conducting channel of 0V isolating the Bulk (i.e. the P-well), hence coupling ratio from Source to FG will be even greater than before, keeping FG at close to 0V. This more efficient approach is illustrated in FIG. 23C.

FIG. 23A, FIG. 23B, and FIG. 23C illustrate implementing row-wise vs. column-wise erase operation for SuperFlash v1-2.

FIG. 23A shows an illustration 2300 of SuperFlash v1-2 (Conventional) Page-wise Erase.

FIG. 23B shows an illustration 2302 of SuperFlash v1-2 according to various embodiments column-wise erase: Option 1.

FIG. 23C shows an illustration 2304 of SuperFlash v1-2 according to various embodiments column-wise Erase: Option 2.

It is to be noted that it is also possible to connect all Source lines (whether they are horizontal or vertical lines) in an array together all the time, and the scheme in FIG. 22B can still be used to program in a column-wise manner. However, in such case, when programming data, the unselected bit-lines must be applied with >0V voltage, e.g. V_{cc}, to inhibit programming, since all Sources of the whole array would be at a high programming voltage of V_{S}_{_}_{pgm}_{_}_{NOR} (as described above), e.g. 8-10V. Despite the simplicity of wiring (i.e. just wire all Source lines together), the drawback with such an approach is that during programming the high programming voltage will be supplied to Source diffusions on all cells in the array, significantly increasing the load of the driver circuit driving the Sources. Also, during erase, the selected word-lines are supplied a high erase voltage V_{WL}_{_}ₑᵣₐₛₑ_{_}_{NOR}, and in order to support column-wise erase, unselected columns must have its bit-lines supplied with a >0V voltage, possibly close to V_{WL}_{_}ₑᵣₐₛₑ_{_}_{NOR}, to inhibit erasing.

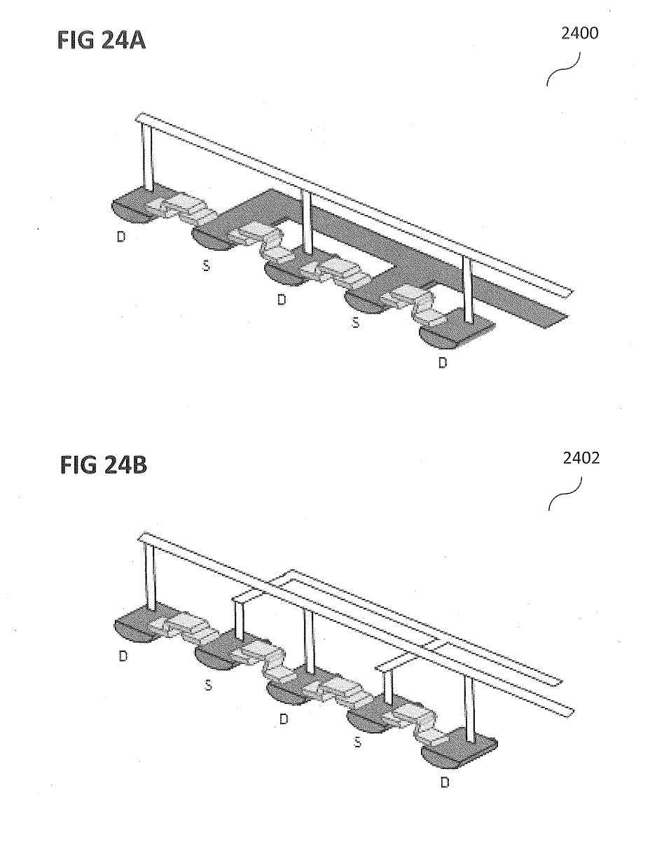

FIG. 24A and FIG. 24B illustrate example ways of merging source diffusions in the same column to form a Source line. A 4-cell long section of a column based on SuperFlash v1-2 is shown. The higher-up line (which connects to D/Drain diffusions) is the metal layer bit-line.

FIG. 24A shows an illustration 2400 of source diffusions merged in the same diffusion layer.

FIG. 24B shows an illustration 2402 of source diffusions merged in metal layer.

The merging of Sources into the Source line may be realized by diffusion extensions, as illustrated in FIG. 24A, or by metal layer wiring, as illustrated in FIG. 24B, or by poly wire (preferably silicided for lower resistance) which would have a wiring layout similar to FIG. 24B. It is to be noted that FIG. 24A and FIG. 24B use SuperFlash v1-2 as an example, but SuperFlash v3 can also be adapted in the same manner by joining the Source line per column as opposed to per row, therefore the corresponding schematic adaptation for v3 is nearly the same as FIG. 22B is therefore omitted for brevity. The only difference is that in SuperFlash v3 there is an Erase Gate (EG) on top of the Source diffusion, so metal or poly based merging has to extend the. Source diffusion slightly at the diffusion layer, to pass (and not touch) the Erase Gate, before merging can be begin. Also, because the Erase Gate which has high voltage during erasing, is shared between the two cells in a cell pair, the conventional SuperFlash v3 page erase would have a smallest granularity of a pair of rows, as opposed to one row in v1-2. Whereas in the adapted column-wise Source line version for SuperFlash v3, the smallest erase unit would still be a column (within an array block), rather than 2 columns.

In the following, a highly scalable and hierarchical priority encoder for reporting matches according to various embodiments will be described.

In the following, a hierarchical design and efficient logic implementation according to various embodiments will be described.

Both the original (one projection compared at a time) and enhanced (multiple projections compared at a time) vote count algorithm described above may increment a vote counter cᵢ for each column i upon each sub-pattern match (whether such a sub-pattern corresponds to a single projection/dimension or multiple projections/dimensions). The columns whose vote counter exceeding or meeting a specified threshold T (i.e. cᵢ>=T) are then considered candidate matches and their column IDs (i.e. index numbers) should then be reported using a priority encoder. Such a priority encoder has N inputs, with a 1 indicating a candidate, 0 otherwise, and it should report whether there is any candidate, and if so, the column IDs of all or part of the candidates. Because the vote count algorithm is intended for large databases, the number of columns N may be very large, making conventional priority encoder (PE) design inefficient. Also, most conventional PEs can only report 1 candidate match.

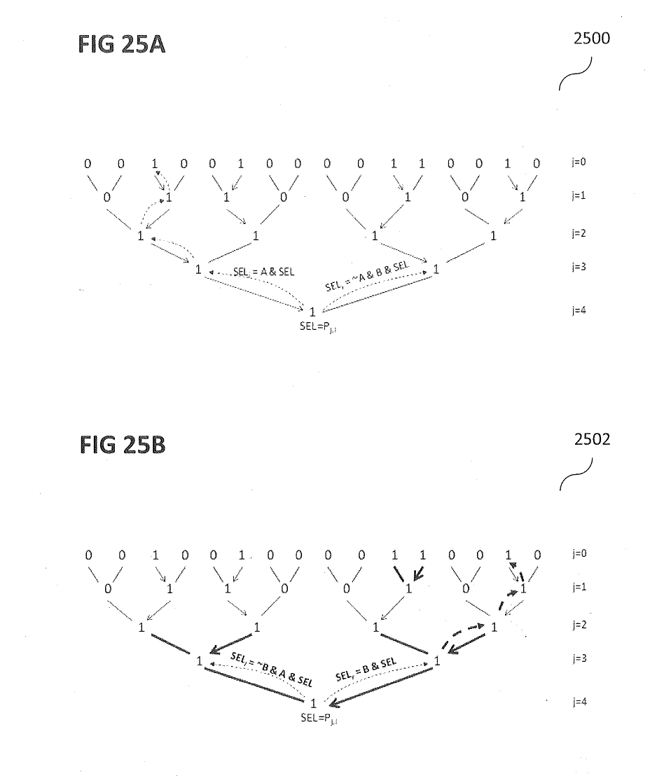

According to various embodiments, a hierarchical priority encoder may be provided, which has a highly scalable design. According to various embodiments, tie-breaking decision may be made in a hierarchical instead of global manner. This is shown in FIG. 25A, where a “left side wins” criterion is used for tie-breaking at every level. Let j denote the level/layer of the priority encoder, where j=0 corresponds to the inputs (which would be the logic result of expression cᵢ>=T when used with the original or enhanced vote count algorithm). Then, the decision of whether there is at least one candidate may be calculated as follows:

P_{j,i}=P_{j-1,2i}|P_{j-1,2i+1} (2)

where P_{j,i} is the i-th value of the hierarchical priority encoder at j-th layer, and i starts from 0 at each layer, and “|” is the logical OR operator. Equation (2) above also applies to “right side wins” criterion which is illustrated in. FIG. 25B.

FIG. 25A and FIG. 25B illustrate hierarchical merging of tie-breaking and feedback of which column to clear after it is reported. A 16-input configuration is illustrated. j designates the hierarchical values at j-th level, with j=0 corresponding to the inputs. A solid arrow designates who is the winner during a tie-breaking event, and a solid un-directed line denotes either no input of 1 or the input of 1 was not the winner. A dashed arrow designates reverse travel to find which input should be cleared after it has been reported. Here “˜” is the logical NOT operator, and “&” is the logical AND operator. In this disclosure the general convention of “˜” having a higher operator precedence than “&” is used. Symbol A and B may be defined like in Table 3.

FIG. 25A shows an illustration 2500 of a “Left side wins” criterion. ‘1’ and ‘0’ denotes logic true and false, respectively.

FIG. 25B shows an illustration 2502 of “Right side wins” criterion, with the same input as (a) at level j=0; Note that lines, arrows, and labels marked in bold shows the specific difference to FIG. 25A.

At the lowest, i.e. root layer (j=log₂N+1) (note we assume N is a power of 2, and if not, the remaining columns may be padded with input of 0 to make it a power of 2) it will be known whether there is at least one match. Then, the column ID of this match (if there is one), can also be determined hierarchically (for both left-side and right-side wins criterion) as shown in Table 3.

TABLE 3
Equations for deriving reported column ID hierarchically.
A: = P_{j-1, 2i}, B: = P_{j-1, 2i+1} where: = denotes a definition operator

| | |
|---|---|
| C_{j, i} = ~A (3a) | C_{j, i} = B (3b) |

C_{j, i}* = C_{j, i} ∥ C_{j-1, k}* where k = 2i + C_{j, i} (4)
where “∥” is the concatenation operator for
concatenating two strings of bits.
C_{1, i} = C_{1, i}* i.e. C_{0, k}* = null string for ∀k. (5)

| | |
|---|---|
| (a) “Left side wins” criterion. | (b) “Right side wins” criterion. |

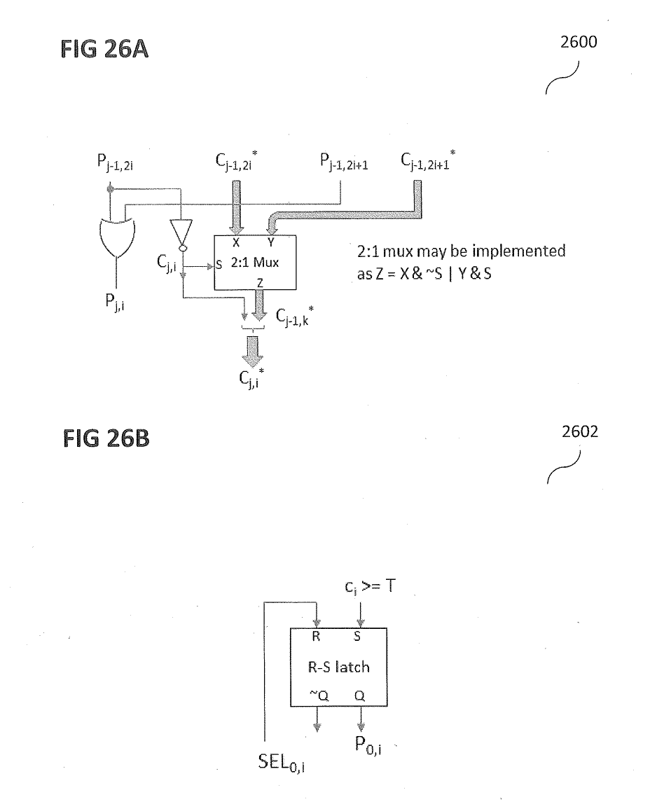

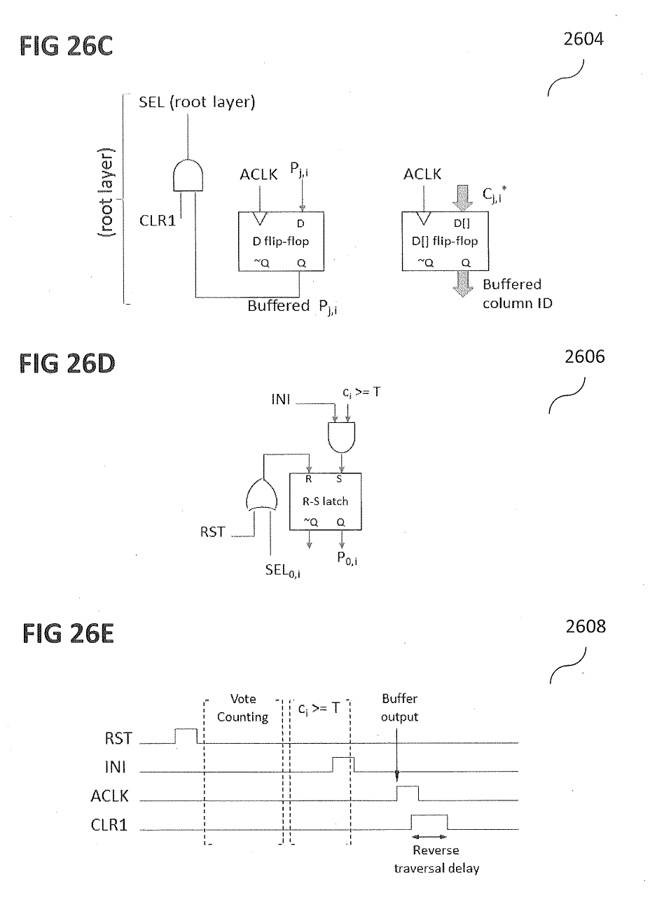

It is to be noted that Equation (4) in Table 3 effectively uses a 2:1 mux, and such a mux can be implemented using, logic gates, as illustrated in FIG. 26A. It is to be noted that Equations (3a) and (3b) are the simplest logic formulas for implementing column ID reporting, this is because when A=B=0, the value of C₃ is don't care, and therefore could take on either 0 or 1. Equation (3a) corresponds to the case of C_{j,i} taking on 1, and Equation (3b) corresponds to the case of C_{j,i} taking on 0, when A=B=0. Of course, an alternative formula for C_{j,i} taking on 0, e.g. C_{j,i}=˜A & B may be used as an alternative to Equation (3a), and similarly an alternative formula for C_{j,i} taking on 1, e.g. C_{j,i}=B|˜A may be used as an alternative to Equation (3b). Note again “˜” has higher operator precedence than “|”, the logical OR operator.

After a winner candidate column is reported, it should be cleared (e.g. by clearing its corresponding input at j=0 layer) so that the priority encoder can report the next winner candidate. One embodiment of implementing this is by having a decoder circuit whose input is the just-reported column ID and whose output are N logic signals with only the signal corresponding to the just-reported column ID being 1 and the rest being 0, and these signals can then be used to control the clearing of the input at j=0 layer. To efficiently clear the input at j=0 layer (instead of having a general decoder which may add additional circuitry overhead), we also present a hierarchical reverse traversal mechanism (for both left-side and right-side wins criterion), as shown in Table 4.

TABLE 4
Equations for efficiently determining which column input to clear
after this column has just been reported, so as to implement
the hierarchical reverse traversal in FIG. 25A and FIG. 25B.
SEL: = SEL_{j, i} where SEL_{j, i} = P_{j, i} for root layer, e.g. j = 4 in FIG. 19. (6)
alternatively, SEL_{j, i} = P_{j, i (buf)} & CLR1 for root layer, (6a)
where P_{j, i (buf)} is a flip - flop buffered version of P_{j, i},
and CLR1 is 1 only when clearing the currently reported column.
SELₗ: = SEL_L_{j, i}: = SEL_{j-1, 2i}. (7)
SELᵣ: = SEL_R_{j, i}: = SEL_{j-1, 2i+1} (8)

| | |
|---|---|
| SELₗ = A & SEL_{j, i} = P_{j-1, 2i} & | SELᵣ = ~B & A & |
| SEL_{j, i} (7a) | SEL_{j, i} = ~(P_{j-1, 2i+1}) |
| | & P_{j-1, 2i} & SEL_{j, i} (7b) |
| SELᵣ = ~A & B & | SELᵣ = B & SEL_{j, i} = P_{j-1, 2i+1} |
| SEL_{j, i} = ~(P_{j-1, 2i}) | & SEL_{j, i} (8b) |
| & P_{j-1, 2i+1} & SEL_{j, i} (8a) | |
| (a) “Left side wins” criterion. | (b) “Right side wins” criterion. |

The sub-expression & SEL_{j,i} in Equations (7a), (7b), (8a), (8b) in Table 5 are important for properly implementing hierarchical reverse traversal as illustrated in FIG. 25A and FIG. 25B, because without it, locally winning arrows at all branches and at all levels will be activated and cause all locally winning input at level j=0 (instead of the just-reported candidate) to be cleared.

As illustrated in FIG. 25A and FIG. 25B, SEₗ and SELᵣ will guide whether to reverse traverse left or right, up the hierarchical tree. At each j-th layer, if SELₗ is logic true, then reverse traversal goes left, and if SELᵣ is logic true, then reverse traversal goes right. By the time the traversal reaches j=0, then input at column i should be cleared if and only if SEL_{0,i} is logic true, and if SEL_{o,i} is false, the input at column i should not be modified. This is illustrated in FIG. 26B, where an R-S latch is used, and the S pin is fed with the vote counter thresholding output (cᵢ>=T), and R pin is fed with SEL_{0,i}. To avoid conflicting input conditions, the S pin should not be logic high when performing reverse traversal, so that there is no chance for both S and R pin to be logic high at the same time for any R-S latch. The elegance of the scheme in FIG. 26B is that no clock input is required. Each column is fed SEL_{0,i}, and the computation of SEL_{j,i} at each layer j may be implemented with combinational logic instead of sequential logic, and if CMOS logic is used (which is typically the case), static power consumption can be low provided transistor leakage is low, and dynamic energy is consumed only if the value of SEL_{j,i} changed, and the change should only occur along the successfully reverse-traversed path, hence consuming very little energy. The use of an R-S latch requires no clock and reduces the need (and the energy required) to push the clock signal to all columns when knowing at most only 1 column will be cleared at a time (e.g. per clock cycle). In addition, and (except for the root/bottom layer and possibly the input/top layer) can also be implemented with combinational logic instead of sequential logic, to both save on transistors and save on energy consumption, especially the energy due to distribution of clock input. Of course, the input to priority encoder may also use devices other than R-S latch, including a clocked (D, J-K, etc.) flip-flop, provided that input at column i (i.e. the output from its corresponding latch or flip-flop) should be cleared only if SEL_{0,i} is logic true, and if SEL_{0,i} is false, the input at column i should not be modified.

To allow reset of all column inputs at level j=0 at the beginning of priority encoding, SEL_{0,i} as illustrated in FIG. 26B may be logically OR′ed with a RESET signal before being fed to the R pin of its corresponding R-S latch, and this RESET signal may be propagated to all column inputs so as to be able to reset all R-S latches when RESET is logic high. This is illustrated in FIG. 26D as the RST signal. After a RESET, an input initialization signal, e.g. INI in FIG. 26D, may be used to latch the comparison results (cᵢ>=T) into the latches or flip-flops corresponding to the PE input. To ensure stable logic operation when clearing the currently (just or to-be) reported (input) column ID, firstly the current PE decision (P_{j,i} at root layer) and its corresponding column ID are buffered into, flip-flops using a clock signal such as ACLK in FIG. 26C (which doesn't have to be a continuous running clock); then, a signal such as CLR1 may be used as illustrated in FIG. 26C to generate the seed of the reverse traversal signal at the right time. FIG. 26E shows an example timing diagram incorporating all these features described in this paragraph. Note the buffered column ID may be reported any time before the next ACLK pulse arrives, and when the next ACLK pulse arrives, it will buffer the next (just or to-be) reported column ID.

In addition to binary branches with hierarchical tie-breaking criterion which has been described above, m-array branches where in inputs at level j is merged into 1 intermediate/final output with a hierarchical tie-breaking criterion, may be used. The formulas for deriving the output decision, column ID (identifier), clearing after report, can all be derived following the working principles described for binary case, and should be familiar to those skilled in the art of digital design in view of the examples above.

FIG. 26A, FIG. 26B, FIG. 26C, FIG. 26D, and FIG. 26E illustrate an hierarchical implementation of candidate column ID reporting and auto-clearing of candidate after being reported.

FIG. 26A shows an illustration 2600 of a hierarchical implementation of reporting column ID determination (example shown for “left side wins” case). When S=0 (logic false), 2:1 Mux outputs value of X (on the Z pin), otherwise it outputs value of Y.

FIG. 26B shows an illustration 2602 of a clock-less input auto-clearing with hierarchical reverse traversal and R-S latch.

FIG. 26C shows an illustration 2604 of a refinement of FIG. 26A at root layer for stable operation; D[ ] denotes a multi-bit D flip-flop with multi-bit input.

FIG. 26D shows an illustration 2606 of a refinement of FIG. 26B for stable operation

FIG. 26E shows an illustration 2608 of an example timing diagram for FIG. 26C and FIG. 26D. It is to be noted that the pulse in RST may also be placed during-or-after “Vote Counting” phase and before the comparison (cᵢ>=T) phase.

In the following, interoperation among priority encoders (Inter-SubArray and Inter-Chip) according to various embodiments will be described.

In the following, Inter-SubArray will be described.

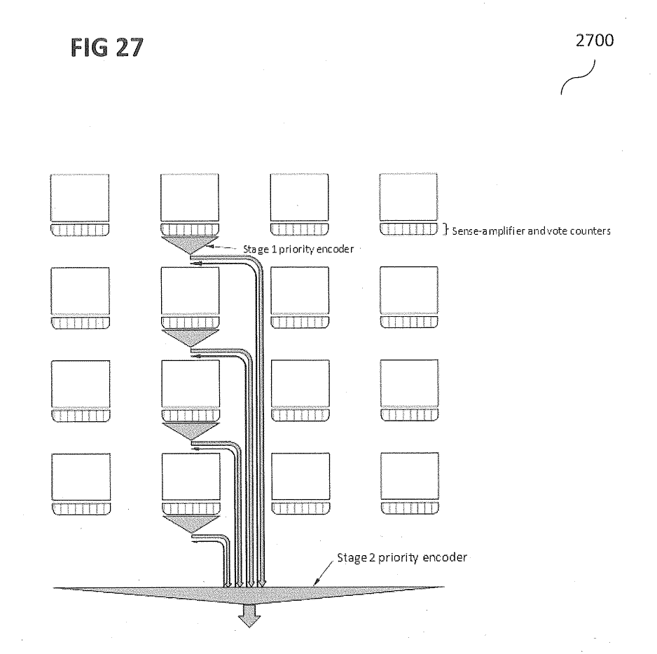

When a memory chip supporting vote-count contains multiple sub-arrays (where a sub-array is defined as the smallest memory cell array that can be operated upon with read and write operations), the queries can be carried out either for specific sub-array or for the entire chip. Each sub-array may have its own set of vote counters and priority encoder, and then the priority encoder for each sub-array (also referred to as a stage-1 priority encoder) may be merged together, hierarchically, into a large-scale priority encoder for the whole chip (the whole encoder minus the stage-1 encoders is also referred to as a stage-2 priority encoder). This is illustrated in FIG. 27.

FIG. 27 shows an illustration 2700 of a hierarchical merging of sub-array priority encoders into a large-scale priority encoder, with an example 16 sub-arrays (4×4 configuration). It will be understood that for brevity, only 4 sub-arrays in the vertical direction are drawn with their stage 1 priority encoders.

When merging, SEL_{j,i} and C*_{j,i} at the root (i.e. bottom layer) of the stage-1 priority encoder are wired to the stage-2 priority encoder via the light-blue data bus shown in FIG. 27. By wiring only SEL_{j,i} and C*_{j,i} at the root layer (instead of all layers), only a small amount of wires are needed on the data bus, providing an easy way to do the chip level layout. Note that SEL_{j,i} and C*_{j,i} at root layer for each sub-array may again be transmitted and operated on using combinational logic, as opposed to sequential logic. Also note that the SELₗ and SELᵣ signals from the top layer of the stage-2 priority encoder must also be propagated back to the root layer of the corresponding stage-1 priority encoder, so that the just-reported column's input can be cleared automatically. This will add 1 wire going to each stage-1 priority encoder from the stage-2 priority encoder, and is indicated by a red curved arrow for each stage-1 priority encoder in FIG. 27. Note that this design with stage-1 and stage-2 priority encoders is essentially the same as a standalone hierarchical priority encoder as described above and in FIG. 25A and FIG. 25B, with the only difference in the geometric layout, because in FIG. 27 the stage-1 priority encoders in the same vertical direction, despite being functionally on the same level/layer, they do not appear at the same horizontal location geometrically.

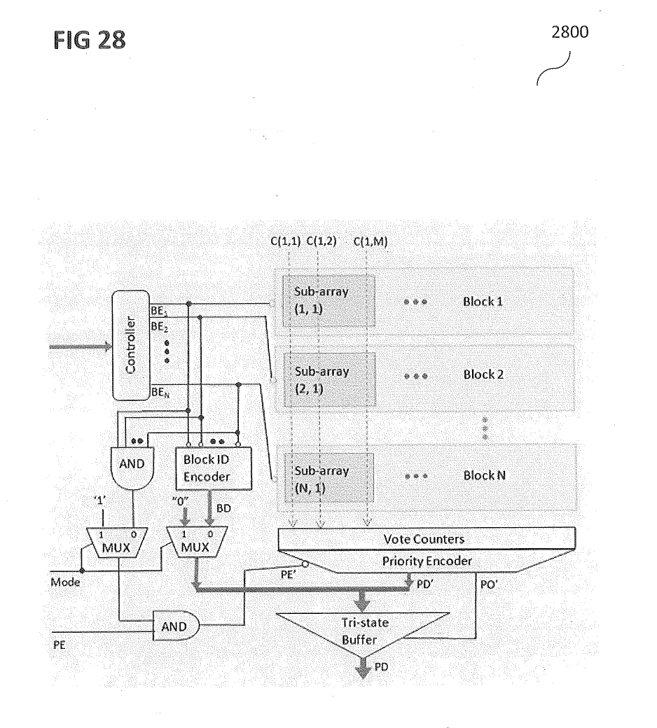

The method of having stage-1 and stage-2 priority encoders, as illustrated in FIG. 27, may not be very efficient in resource usage (such as transistor count). According to various embodiments, a more efficient method may be provided with multiple sub-arrays sharing a same set of vote counters and a priority encoder as, long as all the sub-arrays share a common set of columns. FIG. 28 shows the block diagram of the method.

FIG. 28 shows an illustration 2800 of a block diagram of a shared priority encoder (and shared vote counters) among multiple sub-arrays according to various embodiments.

The major concept is to have a simple control logic “mode” to let the chip work on sub-array level or on chip level. Suppose there are N blocks totally on the chip, because different blocks share a common set of columns, there could be only one block being activated at one moment during the query process. We use BEᵢ (i ∈ {1, . . . , N}) to denote block enabling signals (‘0’ active) generated from the on-chip controller. We use SA_{i,1} (i ∈ {1, . . . , N} to denote the 1^{st} sub-array in block i as shown in FIG. 28, all these sub-arrays share the same set of columns marked as C_{1,m} (m ∈ {1, . . . , M}).

The difference between sub-array level and chip level is that the former requires the priority encoder (and the vote counters) to work for each SA_{i,1}(i ∈ {1, . . . , N}) and report the matched column IDs in the respective sub-arrays separately while the latter requires the priority encoder to wait until all the SA_{i,1} (i ∈ {1, . . . , N}) have been activated (i.e., their sub-pattern matching and vote-counting done) and then report the matched column IDs. BEᵢ (i ∈ {1, . . . , N}) signal sequences are the same in both modes. There are 2 tasks for the control logic signal “mode” to do, one is to control the timing of PE′ (the enabling signal for the collective sequence of vote counting, threshold count comparing and priority encoding) being activated, the other is to have the matched column IDs to include the location information of each sub-array when working on sub-array level. These are achieved by the on-chip logics as shown in FIG. 28 and are summarized as following:

1) Sub-array level (mode=0)
PE′=BE₁ BE₂ ∩ . . . ∩ BE_{N}, it is assumed that in this mode PE=1;
PD=BD∥PD′ when PO′ is ‘1’;
   where BD is log₂N bit encoded block ID and the symbol “∥” means concatenating BD and PD′ together, i.e., prefixing the matched column ID (PD′) with BD. The symbol “∩” denotes logical AND operator.

2) Chip level (mode=1)
PE′=PE;
PD=“0”∥PD′ when PO′ is ‘1’;
   where PE is the priority encoder enabling signal being assigned from outside, which will be ‘0’ when it is time to perform the collective sequence of sub-pattern matching, vote counting, threshold count comparing and priority encoding, and can be used for inter-chip case.

In the following, Inter-Chip according to various embodiments will be described.

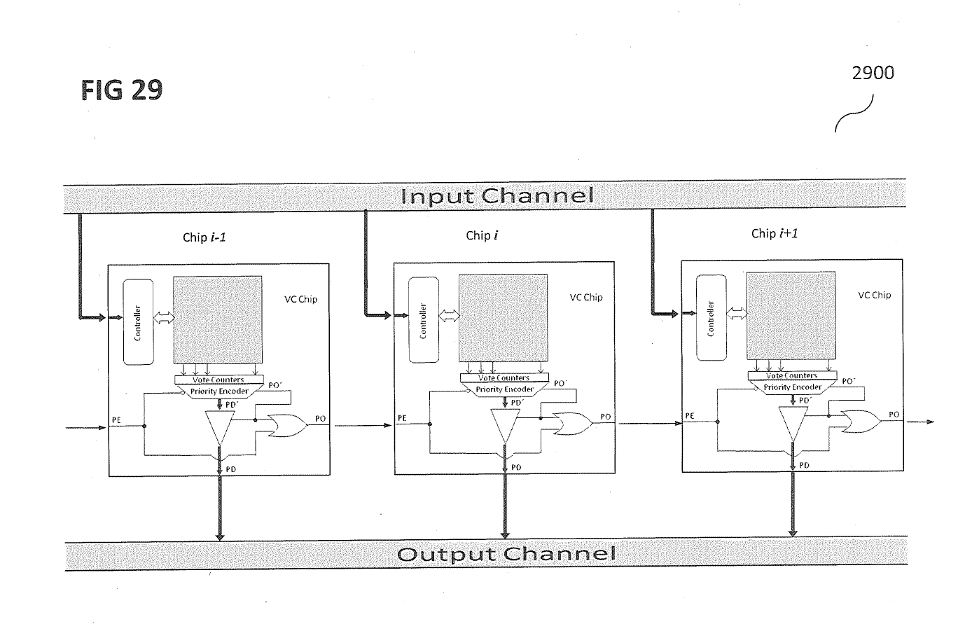

When a query is performed among multiple memory chips supporting original or enhanced vote count (each generally referred to as a VC chip), it is expected that the input of query string to the VC-chips and the output of the matched column IDs should be the same as those for single VC-chip. According to various embodiments, a highly scalable serialized design, for example as shown in FIG. 29, may be provided, which can be used for large database applications.

FIG. 29 shows an illustration 2900 of a scalable inter-chip design according to various embodiments.

According to various embodiments, the following signals may be defined:

PE—Priority encoder enabling signal which is ‘0’ active, i.e., the priority encoder will only start to work when PE=‘0’. Note that PE is also the serialized input signal of the VC-chip.

PO′—Priority encoder output indicating signal which is IDs active, i.e., there is at least one matched column ID only when PO′=‘1’.

PO—The serialized output signal of the VC-chip.

PD′—A sequenced output of matched column IDs from the priority encoder.

PD—The tri-state output which can be connected to the output channel.

The Input Channel and Output Channel in this design refer to the shared data bus among all the VC-chips, which, could be a number of PCIe lanes, a number of AMBA AXI channels, etc. It will be understood that according to various embodiments, various different specific data bus standards may be used.

The on-chip logic for the above defined signals may be:

$${PE}_{i} = {PO}_{i - 1} = {PE}_{i - 1} ⋃ {PO}_{i - 1}^{′}$$

$${PO}_{i}^{′} = \{ \begin{matrix}1 , & if ∃ matched column ID in chip i , and {PE}_{i} = 0 \\ 0 , & if ∄ matched column ID in chip i , or {PE}_{i} = 1\end{matrix} \\ {PD}_{i} = \{ \begin{matrix}{PD}_{i}^{′} & if {PO}_{i}^{′} = 1 \\ hi \text{-} Z , & if {PO}_{i}^{′} = 0\end{matrix}$$

with initial condition PE₁=0. The symbol “∩” denotes logical OR operator.

There may be several advantages according to various embodiments:

1) Simplicity—The entire query output process (also can be referred to as “aggregated priority encoder output”) is started by asserting PE₁ to ‘0’ and the ending of the process is indicated by PO_{N}, where N is the total number of VC-chips.

2) High efficiency—There is no single cycle being wasted between the outputs from any 2 consecutive VC-chips. In case chip i (i ∈ {1, . . . , N}) has no matched column ID to output, the priority encoder of chip i+1 will be started immediately.

3) Scalability and flexibility—As long as the first and the last VC-chips are concerned, there could be any number of VC-chips in between. Any VC-chip can be removed from the chain by simply short-circuiting its PE and PO pins. Similarly, adding one VC-chip into the chain is also straightforward.

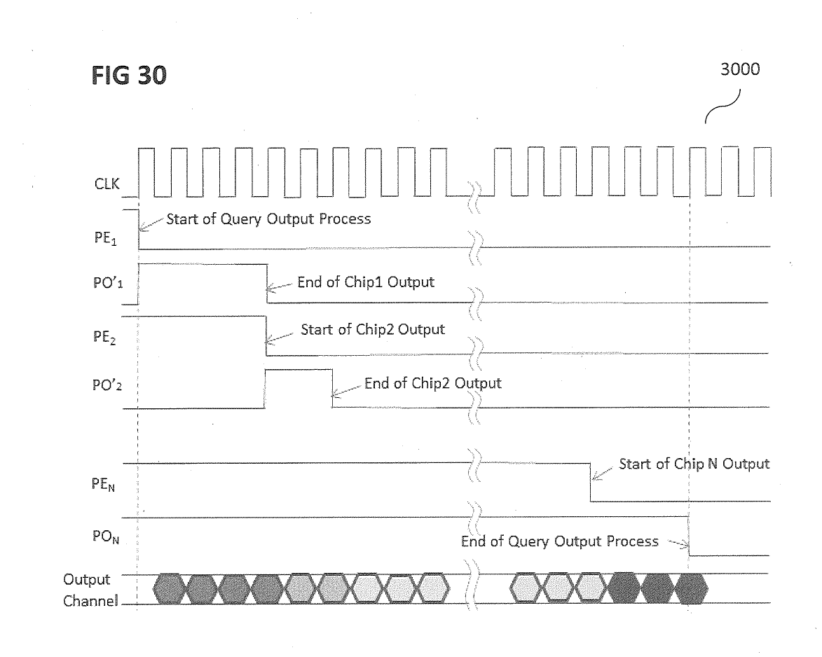

FIG. 30 illustrates those advantages through a timing sequence of the complete query output process.

FIG. 30 shows an illustration 3000 of an example timing sequence of the complete query output process according to various embodiments.

In the following, design optimizations for IC layout and heat dissipation considerations according to various embodiments will be described.

In the vote count algorithm without the interlocked design, activating all sub-arrays simultaneously (for matching against a query sub-pattern) may use too much power. To address this high power consumption and its resulting high heat dissipation issue, it can be arranged such that only some sub-arrays may be activated at a time instead. For example, all sub-arrays on the same horizontal level may be activated simultaneously, while other levels are not activated. Then, on the next access cycle, all sub-arrays on the next horizontal level are activated simultaneously, and so on.

In addition, such mode of operation allows saving of transistors for priority encoder and vote counters, by sharing such circuits across various horizontal levels. For example, in contrast to FIG. 27 where each sub-array has its own vote counters and stage-1 priority encoder, those may be shared within the same vertical direction and FIG. 28 shows one way to implement such sharing. However, this will require many more wires to send the cᵢ>=T signals to where the shared vote counters and priority encoder are located, which may mean more and longer wiring overhead and potentially more electrical noise interference due to these long wires. To reduce wiring difficulty, a single shared metal line at a higher metal layer may be used per column and the multiple sense amplifiers on that column (e.g. one sense-amp per sub-array) may attach their outputs to this metal line via a select transistor such that only the select transistor corresponding to the activated sub-array will be turned on. Once the priority encoder and vote counters are shared by sub-arrays in the same vertical direction, the priority encoder has to wait for the entire vote counting procedure (e.g. comparing L projections) to finish, for the sub-array level (mode=‘0’) in FIG. 29, the VC chip has to execute all L (or L′=L/m when in projections are compared at a time in enhanced vote count) rounds of vote counting for all sub-arrays in the same horizontal level, perform priority encoding and reporting, before it can perform all L projection comparisons, vote counting and priority encoding and reporting for all sub-arrays in the next horizontal level, and so on. And, the reported candidate column ID has to be prefixed by the sub-array ID, as illustrated in FIG. 29.

Also, if a VC chip with no priority encoder or vote counter sharing is designed to report say the first 8 candidates, and there are 4 sub-arrays in the same vertical direction, then using priority encoder and vote counter sharing we may ask the VC chip to report the first 2 candidates per horizontal level, so that after processing all 4 horizontal levels the chip will at most report 8 candidates. However, the exact list of reported candidates may differ between the sharing and non-sharing case even when the database is the same and the same query pattern is used across the two cases. This is because by sharing the priority encoder, the output priority is also changed. For some applications, this discrepancy may not be a real issue.

DRAM, which can be used for implementing the vote count algorithm, generally shares a sense-amplifier between two adjacent bit-lines from either two adjacent sub-arrays (in Open array architecture), or two adjacent columns in the same sub-array (in Folded array architecture). Only one of these two bit-lines may be sensed at a time, because the other bit-line is used to provide a reference voltage to the sense-amplifier. This is similar in spirit to NAND Flash's Shielded bit-line sensing scheme as described above, therefore for all such bit-line pairs, we also refer to them as even and odd bit-lines, respectively.

In the presence of such sense-amplifier sharing, if transistor saving is preferred, the vote counters and priority encoder may also be shared by the even and odd bit-lines, then similar to the sharing of vote counters and priority encoder described above, the VC chip would need to perform the entire vote counting and priority encoding and reporting procedure for the even bit-lines before performing the same procedure for the odd bit-lines (or vice versa). And similarly the priority encoder's reported candidates could be different compared to the case with no priority encoder or vote counters sharing. When no priority encoder or vote counters are shared in DRAM-based vote count implementation, a 1:2 demux may be needed to route the shared sense amplifier's output to the vote counter circuit corresponding to either the even or odd bit-line.

Because NAND Flash's Shielded bit-line sensing scheme as described above, typically shares the sense-amplifier between two adjacent bit-lines, sometimes even with two additional such bit-lines from an adjacent sub-array, it is quite similar in spirit to DRAM's shared sense amplifier, and therefore in such case the vote counters and priority encoder may also be shared by those bit-lines sharing the sense amplifier, just like in the DRAM case, and it would need to perform the entire vote counting and priority encoding and reporting procedure for the even bit-lines before performing the same procedure for the odd bit-lines (or vice versa). If the sense-amplifier is shared by another two bit-lines from an adjacent sub-array, then the entire vote counting and priority encoding and reporting procedure has to be performed for the even and followed by odd bit-lines in one sub-array (or vice versa), before the same steps can be applied to the even and followed by odd bit-lines in the other, adjacent sub-array.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A testing apparatus comprising:
a cell pair comprising two k-state memory cells configured to represent a stored pattern of a k-state value; and
a converter configured to convert a query pattern of a k-state value into at least a pair of voltages defined such that when applied to gates of the cell pair, the voltages make the cell pair into either a high resistance mode or a low resistance mode, depending on whether the query pattern matches the stored pattern.

2. The testing apparatus of claim 1, where the said voltages make the cell pair into high resistance mode when the query pattern matches the stored pattern and into low resistance mode when the query pattern does not match the stored pattern.

3. The testing apparatus of claim 1, where the cell is made of a transistor serially connected to a programmable resistive element, the voltages make the cell pair into low resistance mode when the query pattern matches the stored pattern and into high resistance mode when the query pattern does not match the stored pattern.

4. The testing apparatus of claim 2, where the k-state memory cells are l-bit memory cells, i.e., k=2^{l}.

5. The testing apparatus of claim 4,
wherein the cell pair comprises at least one cell type of of 1-Tr NOR Flash, 2TS NOR Flash, SuperFlash v1-2, SuperFlash v3,
wherein state 0 designates an erased cell, and a larger state number designates a more programmed cell, and 2^{l}−1 designates a most programmed cell, wherein the cell pair with a state pair of (i, 2^{l}−i−1) is used to represent a stored pattern of value i,
wherein a query pattern of value i is converted to a pair of voltages f(i), f(2^{l}−i−1),
where f(i) is a monotonic increasing function of i, and also satisfying f(i)>=Vₜₕ(i−1) && f(i)<Vₜₕ (i), where Vₜₕ(i) is the threshold voltage (as seen from the control gate or word-line) of a cell with state i, and the said voltage pair is then applied to the word-lines of the said cell pair.

6. The testing apparatus of claim 4,
wherein l equals 1; and
wherein the cell pair comprises at least one cell type of of 1-Tr NOR Flash, 2TS NOR Flash, SuperFlash v1-2, SuperFlash v3, or NGMEM.

7. The testing apparatus of claim 6,
wherein the cell type is one of 1-Tr NOR Flash, 2TS NOR Flash, SuperFlash v1-2, SuperFlash v3,
wherein a cell pair with (erased, programmed) state pair is used to represent a stored pattern of “1”, and with (programmed, erased) state is used to represent a stored pattern of “0”,
wherein a query pattern of “1” is converted to a pair of (lo, mid) voltages which are then applied to the word-lines of the said cell pair,
wherein a query pattern of “0” is converted to a pair of (mid, lo) voltages which are then applied to the word-lines of the said cell pair,
wherein a voltage sufficiently high to turn on the select transistor in the case of 2TS NOR Flash, denoted as V_{cc}, is applied to the gates of the select transistors of the said cell pair.

8. The testing apparatus of claim 6,
wherein the cell type is 2TS NOR Flash,
wherein a cell pair with (erased, programmed) state pair is used to represent a stored pattern of “1”, and a cell pair with (programmed, erased) state is, used to represent a stored pattern of “0”,
wherein a query pattern of “1” is converted to a pair, of (mid, mid) voltages which are then applied to the word-lines of the cell pair, and also to a pair of (0V, V_{cc}) voltages which are then applied to the gates of the select transistors of the said cell pair,
wherein a query pattern of “0” is converted to a pair of (mid, mid) voltages which are then applied to the word-lines of the cell pair, and also to a pair of (V_{cc}, 0V) voltages which are then applied to the gates of the select transistors of the said cell pair,
wherein V_{cc} is a voltage sufficiently high to turn on the select transistors of the said cell pair.

9. The testing apparatus of claim 6,
wherein the cell type is NGMEM,
wherein a cell pair with (L, H) resistance state pair is used to represent a stored pattern of “1”, and with (H, L) resistance state pair is used to represent a stored pattern of “0”,
wherein a query pattern of “1” is converted to a pair of (lo, mid) voltages, and applied to the gates of the said cell pair,
wherein a query pattern of “0” is converted to a pair of (mid, lo) voltages, and applied to the gates of the said cell pair,
wherein mid denotes a voltage sufficiently high to turn on the transistor in an NGMEM cell, and lo denotes a voltage sufficiently low to turn off the transistor in an NGMEM cell.

10. A hierarchical priority encoder comprising:
a multi-match controller configured to report multiple matches in case of multiple matches.

11. The hierarchical priority encoder of claim 10, further comprising:
a merging circuit configured to provide hierarchical merging.

12. The hierarchical priority encoder of claim 10,
wherein the multi-match controller is configured to report multiple matches by clearing a previously reported match after each report.

13. The hierarchical priority encoder of claim 12,
wherein the multi-match controller is configured to provide a hierarchically back-traverse mechanism.

14. The hierarchical priority encoder of claim 12,
wherein the multi-match controller is configured to provide a general column-ID to N decoder.

15. The hierarchical priority encoder of claim 10,
wherein the hierarchical priority encoder is configured for multi-array operation.

16. The, hierarchical priority encoder of claim 10,
wherein the hierarchical priority encoder is configured for multi-chip operation.

17. A method for controlling a testing apparatus, the method comprising:
controlling a cell pair of the testing apparatus, a cell pair comprising two k-state memory cells configured to represent a stored pattern of a k-state value; and
converting a query pattern of a k-state value into at least a pair of voltages defined such that when applied to gates of the cell pair, the voltages make the cell pair into either a high resistance mode or a low resistance mode, depending on whether the query pattern matches the stored pattern.

18. The method of claim 17,
wherein the said voltages make the cell pair into high resistance mode when the query pattern matches the stored pattern and into low resistance mode when the query pattern does not match the stored pattern.

19. The method of claim 17,
where the cell is made of a transistor serially connected to a programmable resistive element, the voltages make the cell pair into low resistance mode when the query pattern matches the stored pattern and into high resistance mode when the query pattern does not match the stored pattern.

20. The method of claim 18, where the k-state memory cells are i-bit memory cells, i.e., k=2^{l}.

21. The method of claim 20,
wherein the cell pair comprises at least one cell type of of 1-Tr NOR Flash, 2TS NOR Flash, SuperFlash v1-2, SuperFlash v3,
wherein state 0 designates an erased cell, and a larger state number designates a more programmed cell, and 2^{l}−1 designates a most programmed cell, wherein the cell pair with a state pair of (i, 2^{l}−i−1) is used to represent a stored pattern of value i,
wherein a query pattern of value i is converted to a pair of voltages f(i), f(2−i−1), where f(i) is a monotonic increasing function of i, and also satisfying f(i)>=Vₜₕ(i−1) && f(i)<Vₜₕ(i), where Vₜₕ(i) is the threshold voltage (as seen from the control gate or word-line) of a cell with state i, and the said voltage pair is then applied to the word-lines of the said cell pair.

22. The method of claim 20,
wherein l equals 1; and
wherein the cell pair comprises at least one cell type of of 1-Tr NOR Flash, 2TS NOR Flash, SuperFlash v1-2, SuperFlash v3, or NGMEM.

23. The method of claim 22,
wherein the cell type is one of 1-Tr NOR Flash, 2TS NOR Flash, SuperFlash v1-2, SuperFlash v3,
wherein a cell pair with (erased, programmed) state pair is used to represent a stored pattern of “1”, and with (programmed, erased) state is used to represent a stored pattern of “0”,
wherein a query pattern of “1” is converted to a pair of (lo, mid) voltages which are then applied to the word-lines of the said cell pair,
wherein a query pattern of “0” is converted to a pair of (mid, lo) voltages which are then applied to the word-lines of the said cell pair,
wherein a voltage sufficiently high to turn on the select transistor in the case of 2TS NOR Flash, denoted as V_{cc}, is applied to the gates of the select transistors of the said cell pair.

24. The method of claim 22,
wherein the cell type is 2TS NOR Flash,
wherein a cell pair with (erased, programmed) state pair is used to represent a stored pattern of “1”, and a cell pair with (programmed, erased) state is used to represent a stored pattern of “0”,
wherein a query pattern of “1” is converted to a pair of (mid, mid) voltages which are then applied to the word-lines of the cell pair, and also to a pair of (0V, V_{cc}) voltages which are then applied to the gates of the select transistors of the said cell pair,
wherein a query pattern of “0” is converted to a pair of (mid, mid) voltages which are then applied to the word-lines of the cell pair, and also to a pair of (V_{cc}, 0V) voltages which are then applied to the gates of the select transistors of the said cell pair,
wherein V_{cc} is a voltage sufficiently high to turn on the select transistors of the said cell pair.

25. The method of claim 22,
wherein the cell type is NGMEM,
wherein a cell pair with (L, H) resistance state pair is used to represent a stored pattern of “1”, and with (H, L) resistance state pair is used to represent a stored pattern of “0”,
wherein a query pattern of “1” is converted to a pair of (lo, mid) voltages, and applied to the gates of the said cell pair,
wherein a query pattern of “0” is converted to a pair of (mid, lo) voltages, and applied to the gates of the said cell pair,
wherein mid denotes a voltage sufficiently high to turn on the transistor in an NGMEM cell, and lo denotes a voltage sufficiently low to turn off the transistor in an NGMEM cell.

26. A method for controlling a hierarchical priority encoder, the method comprising:
controlling a multi-match controller of the hierarchical priority encoder to report multiple matches in case of multiple matches.

27. The method of claim 26, further comprising:
controlling a merging circuit to provide hierarchical merging.

28. The method of claim 26,
wherein the multi-match controller reports multiple matches by clearing a previously reported match after each report.

29. The method of claim 28,
wherein the multi-match controller provides a hierarchically back-traverse mechanism.

30. The method of claim 28,
wherein the multi-match controller provides a general column-ID to N decoder.

31. The method of claim 26,
wherein the hierarchical priority encoder provides multi-array operation.

32. The method of claim 26,
wherein the hierarchical priority encoder provides multi-chip operation.
